(19) United States
(12) Patent Application Publication
(10) Pub. No.: US 2025/0185293 A1
(43) Pub. Date: Jun. 5, 2025

(54) INTEGRATED CIRCUIT DEVICE

(71) Applicant: SAMSUNG ELECTRONICS CO., LTD., SUWON-SI (KR)

(72) Inventors: Taesun Kim, Suwon-si (KR); Sangjine Park, Suwon-si (KR)

(21) Appl. No.: 18/761,431

(22) Filed: Jul. 2, 2024

(30) Foreign Application Priority Data
Dec. 5, 2023 (KR) 10-2023-0174887

(51) Int. Cl. H01L 29/417; H01L 21/285; H01L 29/06; H01L 29/40; H01L 29/423; H01L 29/66; H01L 29/775; H01L 29/786

(52) U.S. Cl. CPC H10D 30/6729; H01L 21/28518; H10D 30/014; H10D 30/43; H10D 30/6735; H10D 30/6757; H10D 62/121; H10D 64/01; H10D 64/017

(57) ABSTRACT

An integrated circuit device comprises a plurality of device isolation layers extending in a first horizontal direction and spaced apart from each other in a second horizontal direction perpendicular to the first horizontal direction; a gap-fill insulating layer disposed between the plurality of device isolation layers; a plurality of gate lines disposed on the gap-fill insulating layer and extending lengthwise in the second horizontal direction; a plurality of source/drain regions disposed between adjacent gate lines of the plurality of gate lines; a plurality of source/drain connection structures disposed under the plurality of source/drain regions; and first and second spacer structures in contact with upper sidewalls of the back side contact. The first and second spacer structures are disposed between the gap-fill insulating layer and the first source/drain connection structure.

### CROSS-REFERENCE TO RELATED APPLICATION

This application claims priority under 35 U.S.C. § 119 to Korean Patent Application No. 10-2023-0174887, filed on Dec. 5, 2023, in the Korean Intellectual Property Office, the disclosure of which is incorporated by reference herein in its entirety.

### TECHNICAL FIELD

The present disclosure relates to an integrated circuit device, and more specifically, an integrated circuit device including a back side contact.

### DISCUSSION OF RELATED ART

The development of electronics technology has driven the downscaling of integrated circuit devices. As semiconductor devices require both high operating speeds and precise operation, research is being conducted to optimize the structure of transistors within these devices.

### SUMMARY

Embodiments of the present disclosure relate to an integrated circuit device with improved reliability.

The task to be solved by the technical idea of the present disclosure is not limited to the above-mentioned task, and other tasks not mentioned may be clearly understood by those of ordinary skill in the art from the following description.

According to an aspect of the present disclosure, there are provided the following integrated circuit devices.

According to embodiments of the present disclosure, an integrated circuit device comprises a plurality of device isolation layers extending in a first horizontal direction and spaced apart from each other in a second horizontal direction perpendicular to the first horizontal direction; a gap-fill insulating layer disposed between the plurality of device isolation layers; a plurality of gate lines disposed on the gap-fill insulating layer and extending lengthwise in the second horizontal direction; a plurality of source/drain regions disposed between adjacent gate lines of the plurality of gate lines; a plurality of source/drain connection structures disposed under the plurality of source/drain regions, the plurality of source/drain connection structures including a first source/drain connection structure and a second source/drain connection structure; a back side contact extending through the gap-fill insulating layer in a third direction perpendicular to the first and second horizontal directions and connected to the first source/drain connection structure; and first and second spacer structures in contact with upper sidewalls of the back side contact. The first and second spacer structures are disposed between the gap-fill insulating layer and the first source/drain connection structure.

According to embodiments of the present disclosure, an integrated circuit device comprises a back side contact; first and second spacer structures surrounding a first portion of the back side contact in a first horizontal direction and having a mirror symmetrical shape with respect to the back side contact; a gap-fill insulating layer surrounding a second portion of the back side contact in the first horizontal direction, the second portion being below the first portion surrounded by the first and second spacer structures; a source/drain connection structure disposed above and in contact with the back side contact; a source/drain region electrically connected to the back side contact through the source/drain connection structure; a plurality of gate lines spaced apart from the source/drain region; and a gate dielectric layer disposed between the source/drain region and the plurality of gate lines. The first and second spacer structures separate the back side contact from the gate dielectric layer, and the back side contact has a first horizontal width at an upper portion that is greater than a second horizontal width at a lower portion.

According to embodiments of the present disclosure, an integrated circuit device comprises a plurality of device isolation layers extending lengthwise in a first horizontal direction and spaced apart from each other in a second horizontal direction perpendicular to the first horizontal direction; a gap-fill insulating layer disposed between two adjacent device isolation layers of the plurality of device isolation layers; at least one nanosheet disposed on the gap-fill insulating layer, spaced apart from a top surface of the gap-fill insulating layer in a vertical direction, and facing the top surface of the gap-fill insulating layer; a gate line surrounding the at least one nanosheet on the gap-fill insulating layer and extending lengthwise in the second horizontal direction; a gate dielectric layer surrounding the gate line and separating the at least one nanosheet from the gate line; a source/drain region adjacent to the gate line on the gap-fill insulating layer and in contact with the at least one nanosheet; a source/drain connection structure in contact with a bottom surface of the source/drain region and including a first semiconductor layer and a second semiconductor layer; a back side contact extending from a bottom surface of the gap-fill insulating layer in the vertical direction and covering a first portion of a bottom surface of the source/drain connection structure; and a first spacer structure and a second spacer structure. Each of the first and second spacer structures has a triangular shape in a cross-sectional view and includes a first surface disposed between the back side contact and the gap-fill insulating layer and covering a second portion of the bottom surface of the source/drain connection structure, the second portion being a remaining portion of the bottom surface not covered by the back side contact; and a second surface in contact with a sidewall of the back side contact.

### BRIEF DESCRIPTION OF THE DRAWINGS

Embodiments of the present disclosure will be more clearly understood from the following detailed description taken in conjunction with the accompanying drawings in which:

FIG. 1 is a plan layout diagram of a cell block of an integrated circuit device according to embodiments of the present disclosure;

FIG. 2 is a plan layout diagram illustrating an integrated circuit device according to embodiments of the present disclosure;

FIG. 3A is a cross-sectional view taken along a line X1-X1′ of FIG. 2;

FIG. 3B is a cross-sectional view taken along a line Y1-Y1′ of FIG. 2;

FIG. 3C is an enlarged cross-sectional view of an area EX2 in FIG. 3A;

FIG. 4 is an enlarged cross-sectional view of an area EX2 in FIG. 3A;

FIGS. 5, 6, 7A, 7B, 8A, 8B, 9A, 9B, 10, 11A, 11B, 12, 13, 14, 15A, 15B, 16A, 16B, 17A, 17B, 18, 19, 20A, 20B, 21A, and 21B are diagrams illustrating a method of manufacturing an integrated circuit device according to embodiments of the present disclosure; and

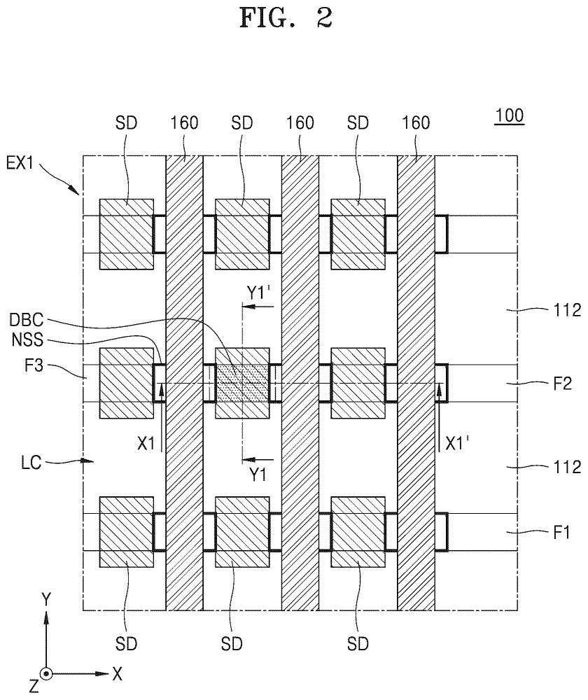

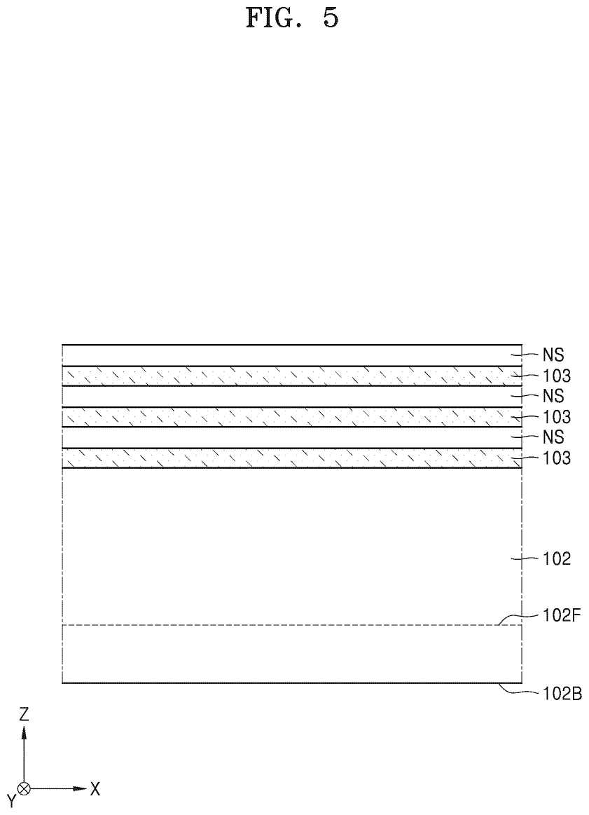

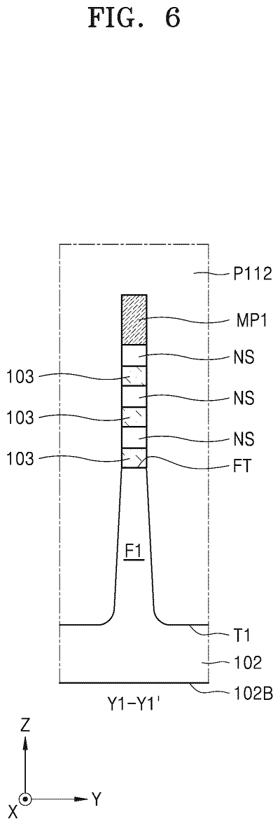

Specifically, FIGS. 5, 7A, 8A, 9A, 11A, 12, 13, 14, 15A, 16A, 17A, 18, 19, 20A, and 21A are diagrams showing a manufacturing process of a portion corresponding to the cross-section of X1-X1′ of FIG. 2, and FIGS. 6, 7B, 8B, 9B, 10, 11B, 15B, 16B, 17B, 20B, and 21B are diagrams showing a manufacturing process of a portion corresponding to the cross-section of Y1-Y1′ of FIG. 2.

### DETAILED DESCRIPTION OF THE EMBODIMENTS

Hereinafter, embodiments of the present disclosure will be described in detail with reference to the accompanying drawings. The same reference numerals are used for the same components in the drawings, and redundant descriptions thereof are omitted.

The present disclosure encompasses various embodiments, and some specific embodiments will be illustrated in the drawings and described in detail. However, this is not intended to limit the scope of the present disclosure for these specific embodiments, and should be understood to include transformations, equivalents, or substitutes that fall within the scope of the disclosed ideas and technologies.

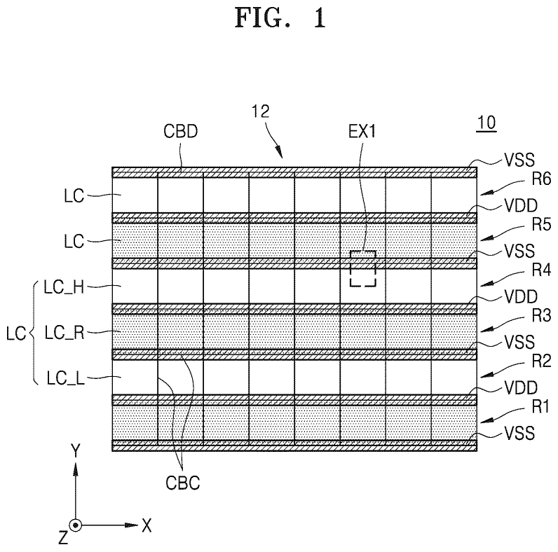

FIG. 1 is a plan layout diagram of a cell block 12 of an integrated circuit device 10 according to embodiments of the present disclosure.

Referring to FIG. 1, the cell block 12 of the integrated circuit device 10 may include a plurality of logic cells LC including circuit patterns for configuring various circuits. The plurality of logic cells LC may be arranged in a matrix form along a first horizontal direction (X direction) and a second horizontal direction (Y direction) within the cell block 12.

The plurality of logic cells LC may include circuit patterns with a layout designed according to a place and route (PnR) technique to perform at least one logical function. The plurality of logic cells LC may be configured to perform various logical functions. In some embodiments, the plurality of logic cells LC may include a plurality of standard cells. In some embodiments, at least some of the plurality of logic cells LC may perform the same logic function. In other embodiments, at least some of the plurality of logic cells LC may perform different logical functions.

The plurality of logic cells LC may include various types of logic cells including a plurality of circuit elements. For example, multiple logic cells LC may include an AND, NAND, OR, NOR, exclusive OR (XOR), exclusive NOR (XNOR), inverter (INV), adder (ADD), buffer (BUF), delay (DLY), filter (FIL), multiplexer (MXT/MXIT), OR/AND/INVERTER (OAI), AND/OR (AO), AND/OR/INVERTER (AOI), D flip-flop, reset flip-flop, master-slave flip-flop, latch, or a combination thereof, but are not limited thereto.

In the cell block 12, at least some of the plurality of logic cells LC forming one row R1, R2, R3, R4, R5, or R6 in the first horizontal direction (X direction) may have the same width. In addition, at least some of the plurality of logic cells LC constituting one row R1, R2, R3, R4, R5, or R6 may each have the same height. However, the technical idea of the present disclosure is not limited to the illustration in FIG. 1, and at least some of the plurality of logic cells LC constituting one row R1, R2, R3, R4, R5, or R6 may have different widths and heights.

The area of each of the plurality of logic cells LC included in the cell block 12 of the integrated circuit device 10 may be defined by a cell boundary CBD. Among the plurality of logic cells LC, cell upper contact parts CBC, where respective cell boundaries CBD meet, may be included between two logic cells LC adjacent to each other in either the first horizontal direction (X direction) or the second horizontal direction (Y direction).

In some embodiments, for the plurality of logic cells LC forming one row R1, R2, R3, R4, R5, or R6, two logic cells LC adjacent to each other in the first horizontal direction may be in contact with each other at the cell upper contact parts CBC without any separation distance between them. In other embodiments, for the plurality of logic cells LC forming one row R1, R2, R3, R4, R5, or R6, two neighboring logic cells LC adjacent to each other in the first horizontal direction (X direction) may be spaced apart from each other with a predetermined separation distance.

In some embodiments, for the plurality of logic cells LC forming one row R1, R2, R3, R4, R5, or R6, two neighboring logic cells LC adjacent to each other may perform the same function. In this case, the two neighboring logic cells LC may have substantially the same structure. In other embodiments, for the plurality of logic cells LC forming one row R1, R2, R3, R4, R5, or R6, two neighboring logic cells LC adjacent to each other may perform different functions.

In some embodiments, any one logic cell LC selected from among the plurality of logic cells LC included in the cell block 12 of the integrated circuit device 10, and another logic cell LC adjacent to the selected logic cell LC in the second horizontal direction (Y direction of FIG. 1), may have a symmetrical structure with respect to the cell upper contact part CBC located between them. For example, a reference logic cell LC_R in the third row R3 and a lower logic cell LC_L in the second row R2 may have a symmetrical structure with respect to the cell upper contact part CBC positioned between them. Similarly, a reference logic cell LC_R in the third row R3 and an upper logic cell LC_H in the fourth row R4 may have a symmetrical structure with respect to the cell upper contact part CBC situated between them.

FIG. 1 illustrates the cell block 12 including six rows R1, R2, R3, R4, R5, and R6, but this is only an example. The cell block 12 may include various numbers of rows selected as needed, and one row may include various numbers of logic cells selected as needed.

One selected from a plurality of ground lines VSS and one selected from a plurality of power lines VDD may be respectively arranged between the plurality of rows R1, R2, R3, R4, R5, and R6, which include the plurality of logic cells LC arranged in a row along the first horizontal direction (X direction). The plurality of ground lines VSS and the plurality of power lines VDD may extend in the first horizontal direction (X-direction) and may be spaced apart from each other in the second horizontal direction (Y-direction). Accordingly, each of the plurality of ground lines VSS and the plurality of power lines VDD may be arranged to overlap the cell boundaries CBD in the second horizontal direction (Y direction) of the logic cell LC.

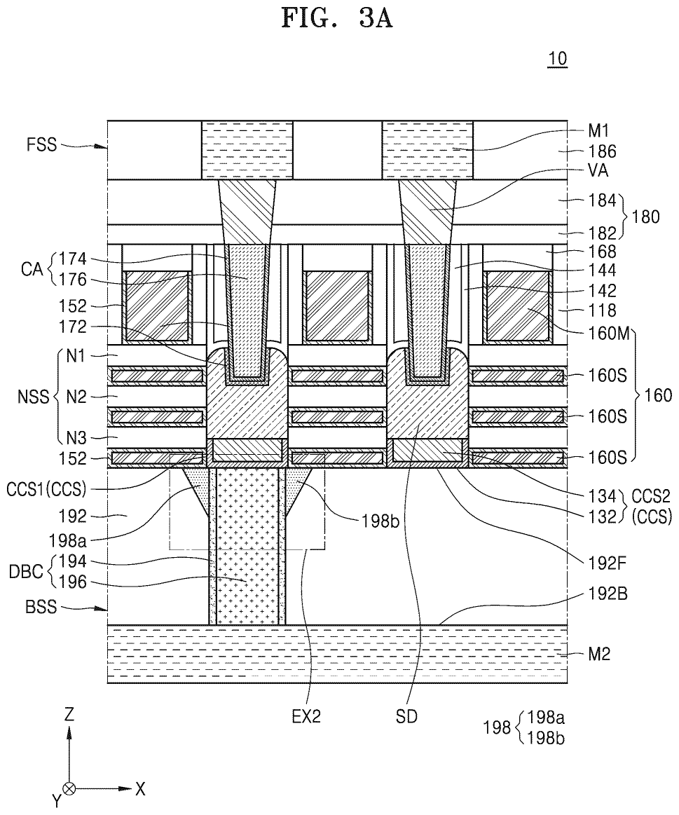

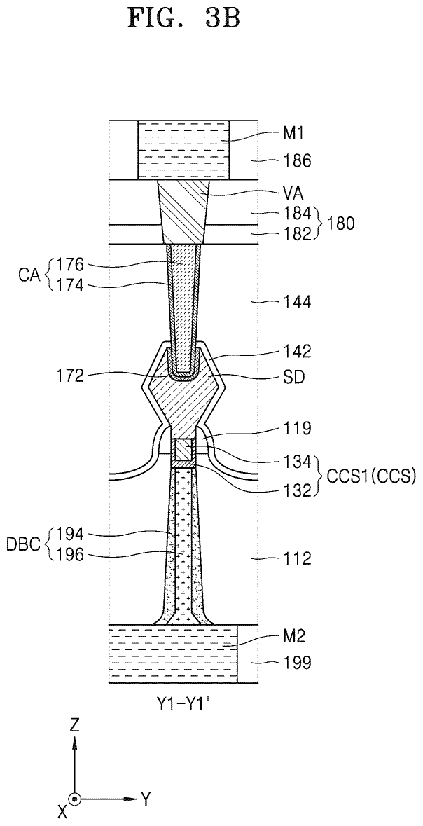

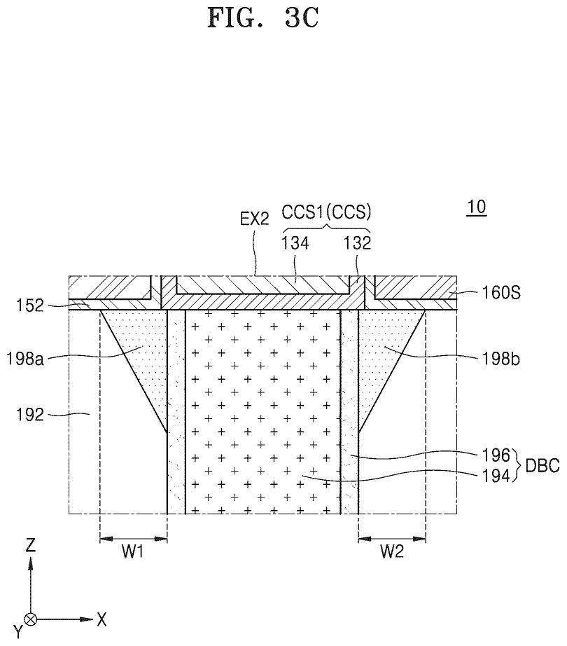

FIG. 2 is a plan layout diagram illustrating an integrated circuit device 10 according to embodiments of the present disclosure. Specifically, FIG. 2 is an enlarged view of an area EX1 of FIG. 1. FIG. 3A is a cross-sectional view taken along a line X1-X1′ of FIG. 2. FIG. 3B is a cross-sectional view taken along a line Y1-Y1′ of FIG. 2. FIG. 3C is an enlarged cross-sectional view of an area EX2 in FIG. 3A.

An integrated circuit device 10, including a field effect transistor having an active area in the shape of a nanowire or nanosheet and a gate-all-around structure including a gate surrounding the active area, is described with reference to FIGS. 2 and 3A to 3C. For example, the integrated circuit device 10 may include a multi-bridge channel FET (MBCFET) device. However, the technical idea of the present disclosure is not limited thereto, and the integrated circuit device 10 may include a planar FET device, a finFET device, and similar structures. The integrated circuit device 10 may constitute some of the plurality of logic cells LC illustrated in FIG. 1.

The integrated circuit device 10 comprises a back side structure BSS and a front side structure FSS disposed on the back side structure BSS. In some embodiments, the back side structure BSS includes a plurality of fin-type active regions F1, a plurality of device isolation layers 112 extending in a first horizontal direction and spaced apart from each other in a second horizontal direction perpendicular to the first horizontal direction, a back side contact DBC disposed between the plurality of device isolation layers 112, first and second spacer structures 198a and 198b in contact with upper sidewalls of the back side contact DBC, a gap-fill insulating layer 192 surrounding the back side contact DBC, a lower wiring layer M2 disposed on a rear surface 192B of the gap-fill insulating layer 192, and a lower insulating layer 199. The gap-fill insulating layer 192 is spaced apart from the back side contact DBC by the first and second spacer structures 198a and 198b.

In some embodiments, the front side structure FSS is disposed on a front side surface 192F of the gap-fill insulating layer 192 and includes a plurality of nanosheet stacks NSS, a plurality of gate lines 160 disposed on the gap-fill insulating layer 192 and extending lengthwise in the second horizontal direction, a source/drain region SD disposed between adjacent gate lines of the plurality of gate lines 160, a source/drain connection structure CCS disposed under the source/drain region SD and including a first source/drain connection structure and a second source/drain connection structure, an insulating liner 142 disposed above the source/drain region SD, and an inter-gate insulating layer 144.

The front side structure FSS of the integrated circuit device 10 may include an active structure. The active structure may include conductive channel region where carriers (electrons or holes) flow and switching operations occur in transistor devices. For example, the active structure may have a fin shape, a nanowire shape, or a nanosheet shape. Although the active structure is illustrated as a nanosheet stack NSS in FIGS. 3A to 3C, the active structure is not limited thereto.

Each of the plurality of nanosheet stacks NSS may include at least one nanosheet facing the front surface 192F of the gap-fill insulating layer 192 at a position spaced apart from the front surface 192F of the gap-fill insulating layer 192 in the vertical direction (Z direction). In embodiments of the present specification, the term “nanosheet” may refer to a conductive structure with a cross-section substantially perpendicular to a current flow direction. A nanosheet may include nanowires.

Each of the plurality of nanosheet stacks NSS may include a first nanosheet N1, a second nanosheet N2, and a third nanosheet N3, which are vertically stacked and overlapping one another in the vertical direction (Z direction). The first nanosheet N1, the second nanosheet N2, and the third nanosheet N3 are positioned at different vertical distances (distances in the Z direction) from the front surface 192F of the gap-fill insulating layer 192. Each of the plurality of gate lines 160 may surround the first nanosheet N1, the second nanosheet N2, and the third nanosheet N3 included in the nanosheet stack NSS overlapping in the vertical direction (Z direction).

Although FIG. 2 illustrates the planar shape of the nanosheet stack NSS as approximately rectangular, the embodiments are not limited to this rectangular shape. The nanosheet stack NSS may have other planar shapes corresponding to the planar shape of each of the gate lines 160. In this example, the plurality of nanosheet stacks NSS and the plurality of gate lines 160 are arranged on the gap-fill insulating layer 192, with the plurality of nanosheet stacks NSS arranged in a line along the first horizontal direction (X direction) on the gap-fill insulating layer 192. However, the number of nanosheet stacks NSS and gate lines 160 arranged on the gap-fill insulating layer 192 can vary and is not restricted to a particular value.

Each of the first nanosheet N1, the second nanosheet N2, and the third nanosheet N3 included in the nanosheet stack NSS may function as a channel region. In some embodiments, each of the first nanosheet N1, the second nanosheet N2, and the third nanosheet N3 may have a thickness selected from about 4 nm to about 6 nm. However, the thickness is not limited thereto Here, the thickness of each of the first nanosheet N1, the second nanosheet N2, and the third nanosheet N3 means a magnitude in the vertical direction (Z direction). According to embodiments, the first nanosheet N1, the second nanosheet N2, and the third nanosheet N3 may have substantially the same thickness in the vertical direction (Z direction) . . . . Alternatively, at least some of the first nanosheet N1, the second nanosheet N2, and the third nanosheet N3 may have different thicknesses in the vertical direction (Z direction). According to embodiments, each of the first nanosheet N1, the second nanosheet N2, and the third nanosheet N3 included in the nanosheet stacks NSS may include a Si layer, a SiGe layer, or a combination thereof.

As illustrated in FIG. 3A, the first nanosheet N1, the second nanosheet N2, and the third nanosheet N3 included in one nanosheet stack NSS may have the same or similar dimensions in the first horizontal direction (X direction). However, in other embodiments, at least one of the nanosheets included in one nanosheet stack NSS may have different dimensions in the first horizontal direction (X direction) . . . . This embodiment illustrates each of the plurality of nanosheet stacks NSS including three nanosheets, but the number of nanosheets constituting the nanosheet stack NSS can vary and is not limited to a specific value.

As shown in FIG. 3A, the plurality of gate lines 160 may extend lengthwise in the second horizontal direction (Y direction) and surround the plurality of nanosheet stacks NSS on the gap-fill insulating layer 192. The gate lines 160 may be parallel to each other. Each gate line 160 may include a main gate part 160M and a plurality of sub-gate parts 160S. The main gate part 160M extends lengthwise in the Y direction and covers the top surface of the nanosheet stack NSS. The plurality of sub-gate parts 160S may be integrally connected to the main gate part 160M, and each of the plurality of sub-gate parts 160S may be arranged between the first nanosheet N1 and the second nanosheet N2, between the second nanosheet N2 and the third nanosheet N3, and between the third nanosheet N3 and the gap-fill insulating layer 192. In the vertical direction (Z direction), the thickness of each of the plurality of sub-gate parts 160S may be less than the thickness of the main gate portion 160M.

Each gate line 160 may comprise a metal, a metal nitride, a metal carbide layer, or a combination of these materials. The metal can be selected from Ti, W, Ru, Nb, Mo, Hf, Ni, Co, Pt, Yb, Tb, Dy, Er, and Pd. The metal nitride may be TiN or TaN, and the metal carbide layer may be TiAIC. However, other materials can also be used for the gate lines 160.

A gate dielectric layer 152 is disposed between the nanosheet stack NSS and the gate line 160. The gate dielectric layer 152 may have a stacked structure including an interface dielectric layer and a high dielectric layer. The interface dielectric layer may include a low dielectric material with a dielectric constant of about 9 or less, such as silicon oxide, silicon oxynitride, or a combination thereof. In some embodiments, the interface dielectric layer may be omitted. The high dielectric layer is made of a material with a higher dielectric constant than that of silicon oxide, ranging from about 10 to about 25. The high dielectric layer may include hafnium oxide, but other materials may also be used.

Both sidewalls of each sub-gate part 160S of the gate lines 160 may be spaced apart from the source/drain region SD, with the gate dielectric layer 152 positioned between them. The gate dielectric layer 152 is arranged between the sub-gate part 160S and each of the nanosheets (N1, N2, N3), as well as between the sub-gate part 160S and the source/drain region SD.

In some embodiments, each of the gate dielectric layer 152 and the gate line 160 may include a portion that is in contact with and overlaps the plurality of nanosheet stacks NSS.

According to the embodiments, a plurality of transistors may be formed in portions where each of the nanosheet stacks NSS, the gate line 160, and the gate dielectric layer 152 overlap. The transistors may include a PMOS transistor and an NMOS transistor. Each transistor may include at least one nanosheet stack NSS, the gate dielectric layer 152, the gate line 160 surrounding the nanosheet stack NSS, and the source/drain regions SD facing the nanosheet stack NSS in the first horizontal direction (X direction).

In some embodiments, each of the nanosheet stacks NSS may include an undoped Si layer. In other embodiments, each nanosheet stack NSS may include a doped Si layer. For a PMOS transistor, the nanosheet stacks NSS may include Si layers doped with p-type dopants, such as boron (B) or gallium (G). In some examples, for an NMOS transistor, the nanosheet stacks NSS may include Si layers doped with n-type dopants, such as phosphorus (P), arsenic (As), or antimony (Sb). However, embodiments of the present disclosure are not limited thereto.

The top surface of each of the gate dielectric layer 152 and the gate line 160 may be covered with a capping insulating pattern 168, which may include a silicon nitride layer or a silicon oxide layer.

Both sidewalls of each gate line 160 and capping insulating pattern 168 may be covered with an outer insulating spacer 118. The outer insulating spacer 118 covers both sidewalls of the main gate part 160M on the top surface of each of the plurality of nanosheet stacks NSS. The outer insulating spacer 118 is spaced apart from the gate line 160, with the gate dielectric layer 152 positioned between them.

As illustrated in FIG. 3B, a plurality of recess-side insulating spacers 119 covering sidewalls of the source/drain region SD may be arranged on the top surface of the device isolation layer 112. In some embodiments, each of the plurality of recess-side insulating spacers 119 may be integrally connected to the adjacent outer insulating spacer 118.

Each of the plurality of outer insulating spacers 118 and the plurality of recess-side insulating spacers 119 may include silicon nitride, silicon oxide layer, SiCN, SiBN, SION, SIOCN, SiBCN, SiOC, or a combination of these materials. The terms “SiCN”, “SiBN”, “SiON”, “SiOCN”, “SiBCN”, and “SiOC” used herein refer to materials including the elements mentioned in each term and do not represent chemical formulae with a stoichiometric relationship.

A metal silicide layer 172 may be formed on the top surface of each of the plurality of source/drain regions SD. The metal silicide layer 172 may include a metal selected from Ti, W, Ru, Nb, Mo, Hf, Ni, Co, Pt, Yb, Tb, Dy, Er, or Pd. For example, the metal silicide layer 172 may include titanium silicide, but is not limited to this material.

The plurality of source/drain regions SD, the plurality of metal silicide layers 172, and the plurality of outer insulating spacers 118 may be covered with an insulating liner 142. In some embodiments, the insulating liner 142 may be omitted. An inter-gate insulating layer 144 may be arranged on the insulating liner 142. When the insulating liner 142 is omitted, the inter-gate insulating layer 144 may be in direct contact with the plurality of source/drain regions SD.

The insulating liner 142 and the inter-gate insulating layer 144 may be sequentially arranged on the plurality of source/drain regions SD and the plurality of metal silicide layers 172. Together, the insulating liner 142 and the inter-gate insulating layer 144 may constitute an insulating structure. In some embodiments, the insulating liner 142 may include silicon nitride, SiCN, SiBN, SION, SIOCN, SiBCN, or a combination of these materials, but is not limited to these options. The inter-gate insulating layer 144 may include a silicon oxide layer, but is not limited to this material.

As illustrated in FIGS. 3A and 3B, a plurality of source/drain connection structures CCS are disposed under the source/drain regions SD. Each source/drain connection structure CCS is disposed below a corresponding source/drain region SD and is in contact with it. The insulating liner 142 and the inter-gate insulating layer 144 are sequentially arranged above each source/drain region SD. This configuration results in the source/drain region SD being positioned between the insulating liner 142 and the source/drain connection structure CCS, as well as between the inter-gate insulating layer 144 and the source/drain connection structure CCS.

The arrangement of the source/drain connection structures CCS can vary depending on the embodiment. In some embodiments, the source/drain connection structures CCS are disposed between adjacent nanosheet stacks NSS that are spaced apart in the first horizontal direction (X direction). In other embodiments, the source/drain connection structures CCS are positioned between adjacent device isolation layers 112 that are spaced apart in the second horizontal direction (Y direction). Additionally, in some embodiments, the source/drain connection structures CCS are located between adjacent recess-side insulating spacers 119 that are spaced apart in the Y direction.

A source/drain connection of the plurality of source/drain connection structures CCS may include a first semiconductor layer 132 and a second semiconductor layer 134. The first semiconductor layer 132 conformally extends along the sidewall and bottom surface of the second semiconductor layer 134. Together, the first and second semiconductor layers 132 and 134 are in contact with the source/drain region SD. A portion of the first semiconductor layer 132 is arranged between the second semiconductor layer 134 and the back side contact DBC, separating the second semiconductor layer 134 from the back side contact DBC. In another embodiment, a portion of the first semiconductor layer 132 is arranged between the second semiconductor layer 134 and the gap-fill insulating layer 192, separating the second semiconductor layer 134 from the top surface 192F of the gap-fill insulating layer 192.

In some embodiments, the first semiconductor layer 132 and the second semiconductor layer 134 may include a silicon layer or an SiGe layer. As used herein, the term “SiGe” refers to a material consisting of the elements silicon and germanium and does not indicate a specific stoichiometric relationship. For example, the first semiconductor layer 132 and the second semiconductor layer 134 may include a monocrystalline silicon layer, a polycrystalline silicon layer, an amorphous silicon layer, a monocrystalline SiGe layer, a polycrystalline SiGe layer, or an amorphous SiGe layer. In some embodiments, the first semiconductor layer 132 may include a silicon layer, and the second semiconductor layer 134 may include an SiGe layer. In other embodiments, both the first semiconductor layer 132 and the second semiconductor layer 134 may include SiGe layers, but the ratios of Ge contained in the first semiconductor layer 132 and the second semiconductor layer 134 may be different.

As illustrated in FIG. 3A, the plurality of gate lines 160 may be arranged on the top surface 192F of the gap-fill insulating layer 192. The gap-fill insulating layer 192 may cover at least a portion of the bottom surface of the lowermost portion of the gate dielectric layer 152. In addition, as illustrated in FIG. 2, the gap-fill insulating layer 192 may be arranged between the plurality of device isolation layers 112 spaced apart from each other.

In some embodiments, the gap-fill insulating layer 192 may include silicon nitride (SiN), silicon oxide (SiO), SiCN, SiBN, SION, SIOCN, SiBCN, SiOC, or a combination of these materials, but is not limited thereto. The terms “SiV”, “SiO”, “SiCN”, “SiBN”, “SiON”, “SiOCN”, “SiBCN”, and “SiOC” used herein refer to materials including the elements mentioned in each term and do not represent chemical formulae with a stoichiometric relationship. In other embodiments, the gap-fill insulating layer 192 may include a low dielectric layer. The low dielectric layer may be fluorine-doped silicon oxide, organosilicate glass, carbon-doped oxide, porous silicon oxide, porous organosilicate glass, spin-on organic polymeric dielectric, spin-on silicon based polymeric dielectric, or a combination of these materials, but is not limited to these examples.

In some embodiments, the back side contact DBC may be arranged under a selected source/drain connection structure CCS from the plurality of source/drain connection structures CCS. In the present specification, a source/drain connection structure CCS connected to the back side contact DBC may be defined as a first source/drain connection structure CCS1. In addition, a source/drain connection structure CCS not connected to the back side contact DBC may be defined as a second source/drain connection structure CCS2. The back side contact DBC may extend through the gap-fill insulating layer 192 and be in contact with the first source/drain connection structure CCS1. In some embodiments, the back side contact DBC may include a back side barrier layer 194 and a back side via 196.

In some embodiments, the back side barrier layer 194 may include a metal or metal nitride. For example, the back side barrier layer 194 may include Ti, Ta, W, TiN, TaN, WN, WCN, TiSiN, TaSIN, WSiN, or a combination of these materials, but is not limited thereto. The back side via 196 may include molybdenum (Mo), copper (Cu), tungsten (W), cobalt (Co), ruthenium (Ru), manganese (Mn), titanium (Ti), tantalum (Ta), aluminum (Al), a combination of these materials, or an alloy containing these materials, but is not limited thereto.

As illustrated in FIG. 3A, the back side contact DBC may be in contact with spacer structures 198a and 198b and the gap-fill insulating layer 192 in the first horizontal direction (X direction). For example, the spacer structures 198a and 198b may cover the upper sidewall of the back side contact DBC in the first horizontal direction (X direction), and the gap-fill insulating layer 192 may cover the lower sidewall of the back side contact DBC in the first horizontal direction (X direction). The spacer structures 198a and 198b may be surrounded by the gate dielectric layer 152, the first source/drain connection structure CCS1, the gap-fill insulating layer 192, and the back side contact DBC. In some embodiments, the spacer structures 198a and 198b may include Si. In addition, as illustrated in FIG. 3B, the back side contact DBC may be in contact with the device isolation layer 112 in the second horizontal direction (Y direction). For example, the device isolation layer 112 may cover a sidewall of the back side contact DBC in the second horizontal direction (Y direction).

In some embodiments, the spacer structures 198a and 198b may cover a portion of the bottom surface of the lowermost portion of the gate dielectric layer 152. A portion of the bottom surface of the gate dielectric layer 152 covered by the spacer structures 198a and 198b may be adjacent to the back side contact DBC. In some embodiments, the spacer structures 198a and 198b may separate the first source/drain connection structure CCS1 from the gap-fill insulating layer 192. For example, the gap-fill insulating layer 192 may be spaced apart from the first source/drain connection structure CCS1 with the spacer structures 198a and 198b positioned between them.

In some embodiments, a back side contact DBC may cover a portion of the bottom surface of the first source/drain connection structure CCS1, and the spacer structures 198a and 198b may cover the remaining portion of the bottom surface of the first source/drain connection structure CCS1.

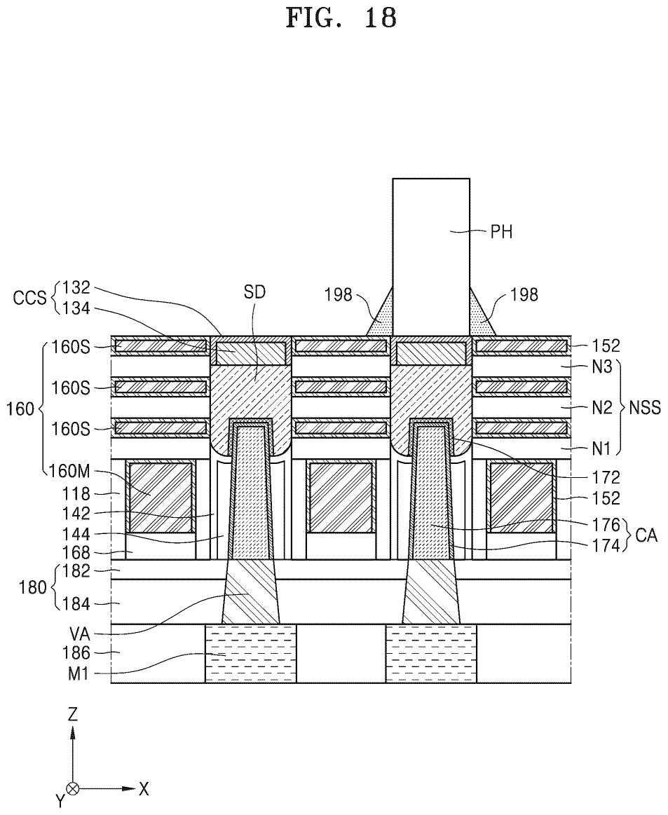

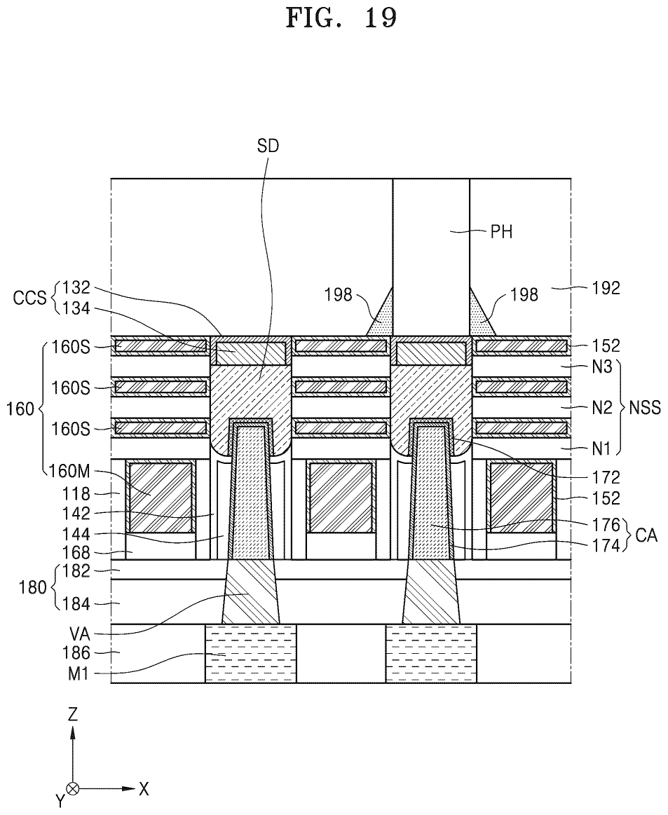

As illustrated in FIG. 3C, the spacer structures 198a and 198b may include the left spacer structure 198a formed at an upper left end of the back side contact DBC and the right spacer structure 198b formed at an upper right end of the back side contact DBC. The left spacer structure 198a and the right spacer structure 198b may be symmetrical to each other with respect to the back side contact DBC, but the embodiments are not limited thereto. The spacer structures 198a and 198b may be a portion of a substrate 102 remaining after an etching process used to form the back side contact DBC. A manufacturing process of a gate protection layer GP is described in detail with reference to FIGS. 18 and 19 below.

In some embodiments, the spacer structures 198a and 198b are formed in a triangular shape and surround a portion of the upper sidewall on both sides of the back side contact DBC. The widths of the spacer structures 198a and 198b are defined as the lengths in the first horizontal direction (X direction) on the uppermost surface of the spacer structures 198a and 198b that are in contact with the gate dielectric layer 152. The width W1 of the left spacer structure 198a may be the same as the width W2 of the right spacer structure 198b, but other configurations are possible. The triangular shape of the spacer structures 198a and 198b, as shown in FIG. 3C, may result from the difference in etching speed based on the crystal orientations of the spacer structures 198a and 198b during a wet etching process (refer to FIG. 18). In some embodiments, the widths W1 and W2 of the spacer structures 198a and 198b may not exceed approximately 2 nm, but other dimensions are possible. The length of the spacer structures 198a and 198b extending in the first horizontal direction (X direction) may depend on the length of the gate line 160 (see FIG. 3A) in the X direction. In some examples, the triangular shape of the spacer structures 198a and 198b may be obtained by an anisotropic etching process, which is influenced by the different etching speeds along various crystal planes, such as the Miller index (111) plane in a cubic crystal system like silicon. The Miller index (111) refers to a specific crystallographic plane in a cubic crystal system, such as the diamond cubic structure found in silicon. This plane may be defined by the intercepts of the crystal lattice vectors at one unit length along each axis, resulting in a triangular arrangement of atoms on the surface.

As shown in FIG. 2, a pair of device isolation layers 112 selected from the plurality of device isolation layers 112 may be spaced apart from each other, with the gap-fill insulating layer 192 positioned between them. The device isolation layers 112 extend lengthwise in the first horizontal direction (X direction) and are parallel to each other. They are spaced apart from each other in the second horizontal direction (Y direction). In some embodiments, the device isolation layer 112 may comprise a silicon oxide layer, a silicon nitride layer, a silicon oxynitride layer, or a combination of these materials. The back side contact DBC is surrounded by the gap-fill insulating layer 192 in the first horizontal direction (X direction) and by the device isolation layer 112 in the second horizontal direction (Y direction).

In addition, a pair of device isolation layers 112 selected from among the plurality of device isolation layers 112 may be spaced apart from each other with a fin-type active region F1 positioned between them. A plurality of fin-type active regions F1 may extend lengthwise in the first horizontal direction (X direction) and may be parallel to each other. The plurality of fin-type active regions F1 may be spaced apart from each other in the second horizontal direction (Y direction). The plurality of fin-type active regions F1 may include semiconductors, such as Si or Ge, or compound semiconductors, such as SiGe, SiC, GaAs, InAs, InGaAs, or InP. The terms “SiGe”, “SiC”, “GaAs”, “InAs”, “InGaAs”, and “InP” used herein refer to materials composed of the elements mentioned in each term and do not represent chemical formulae with a stoichiometric relationship.

In some embodiments, the gap-fill insulating layer 192 may extend lengthwise in the first horizontal direction (X direction) between the plurality of device isolation layers 112. In other embodiments, the gap-fill insulating layer 192 may extend in the first horizontal direction (X direction) between the plurality of device isolation layers 112 and may be in contact with the fin-type active region F1 adjacent to the gap-fill insulating layer 192 in the first horizontal direction (X direction).

As illustrated in FIG. 3B, the device isolation layer 112 may cover a sidewall of the back side contact DBC. In some embodiments, the device isolation layer 112 may cover at least a portion of the sidewall of the source/drain connection structure CCS, and the plurality of recess-side insulating spacers 119 may cover the remaining portion of the sidewall of the source/drain connection structure CCS. In other embodiments, the device isolation layer 112 may not cover the sidewall of the source/drain connection structure CCS, but the plurality of recess-side insulating spacers 119 may cover the entire sidewall of the source/drain connection structure CCS.

A plurality of source/drain contacts CA may be arranged on the plurality of source/drain regions SD. Each of the plurality of source/drain contacts CA may extend through the inter-gate insulating layer 144 and the insulating liner 142 in the vertical direction (Z direction) to be in contact with the metal silicide layer 172. Each of the plurality of source/drain contacts CA may be configured to be electrically connected to the source/drain regions SD through the metal silicide layer 172. Each of the plurality of source/drain contacts CA may be spaced apart from the main gate part 160M in the first horizontal direction (X direction) with the outer insulating spacer 118 positioned between them.

The plurality of source/drain contacts CA may include a conductive barrier pattern 174 and a contact plug 176 sequentially stacked on the source/drain region SD. The conductive barrier pattern 174 may surround the bottom surface and the sidewall of the contact plug 176 and may be in contact with the bottom surface and the sidewall of the contact plug 176. Each of the plurality of source/drain contacts CA may extend through the inter-gate insulating layer 144 and the insulating liner 142 and may extend lengthwise in the vertical direction (Z direction). The conductive barrier pattern 174 may be arranged between the metal silicide layer 172 and the contact plug 176. The conductive barrier pattern 174 may have a surface in contact with the metal silicide layer 172 and a surface in contact with the contact plug 176. In some embodiments, the conductive barrier pattern 174 may include a metal or metal nitride. For example, the conductive barrier pattern 174 may include Ti, Ta, W, TiN, TaN, WN, WCN, TiSiN, TaSIN, WSIN, or a combination of these materials, but is not limited thereto. The contact plug 176 may include molybdenum (Mo), copper (Cu), tungsten (W), cobalt (Co), ruthenium (Ru), manganese (Mn), titanium (Ti), tantalum (Ta), aluminum (Al), a combination of these materials, or an alloy containing these materials, but is not limited thereto.

The top surface of each of the plurality of source/drain contacts CA, the plurality of capping insulating patterns 168, and the inter-gate insulating layer 144 may be covered with an upper insulating structure 180. The upper insulating structure 180 may include an etching stop layer 182 and an interlayer insulating layer 184 sequentially stacked on each of the plurality of source/drain contacts CA, the plurality of capping insulating patterns 168, and the inter-gate insulating layer 144. The etching stop layer 182 may include a silicon carbide (SIC), SiN, a nitrogen-doped silicon carbide (SiC:N), SiOC, AlN, AION, AIO, AlOC, or a combination of these materials. The interlayer insulating layer 184 may include an oxide layer, a nitride layer, an ultra low-k (ULK) layer with an ultra low dielectric constant K ranging from about 2.2 to about 2.4, or a combination of these materials. For example, the interlayer insulating layer 184 may include a tetraethylorthosilicate (TEOS) layer, a high density plasma (HDP) oxide layer, a boro-phospho-silicate glass (BPSG) layer, a flowable chemical vapor deposition (FCVD) oxide layer, a SiON layer, a SiN layer, a SiOC layer, a SiCOH layer, or a combination of these materials, but is not limited thereto.

A plurality of source/drain via contacts VA may be respectively arranged on the plurality of source/drain contacts CA. Each of the plurality of source/drain via contacts VA may extend through the upper insulating structure 180 and be in contact with the source/drain contacts CA. Each of the plurality of source/drain regions SD may be configured to be electrically connected to the source/drain via contacts VA through the metal silicide layer 172 and the source/drain contact CA. The bottom surface of each of the plurality of source/drain via contacts VA may be in contact with the top surface of the source/drain contact CA. Each of the plurality of source/drain via contacts VA may include molybdenum (Mo) or tungsten (W), but is not limited to these materials.

The top surface of each of the upper insulating structure 180 and the plurality of source/drain via contacts VA may be covered with the upper insulating layer 186. The materials constituting the upper insulating layer 186 are substantially the same as those described above for the interlayer insulating layer 184.

The upper wiring layer M1 may extend through the upper insulating layer 186 to be connected to one source/drain via contact VA selected from among the plurality of source/drain via contacts VA under the upper wiring layer M1. The upper wiring layer M1 may include molybdenum (Mo), copper (Cu), tungsten (W), cobalt (Co), ruthenium (Ru), manganese (Mn), titanium (Ti), tantalum (Ta), aluminum (Al), a combination of these materials, or an alloy containing these materials, but is not limited thereto.

The bottom surface of each of the device isolation layer 112, the gap-fill insulating layer 192, and the back side contact DBC may be covered with the lower insulating layer 199. The materials constituting the lower insulating layer 199 are substantially the same as those described above for the interlayer insulating layer 184.

The lower wiring layer M2 may extend through the lower insulating layer 199 to be connected to the back side contact DBC on the upper part of the lower wiring layer M2. The lower wiring layer M2 may include molybdenum (Mo), copper (Cu), tungsten (W), cobalt (Co), ruthenium (Ru), manganese (Mn), titanium (Ti), tantalum (Ta), aluminum (Al), a combination of these materials, or an alloy containing these materials, but is not limited thereto.

According to embodiments of the technical idea of the present disclosure, the spacer structures 198a and 198b surround both upper sidewalls of the back side contact DBC to prevent unnecessary current from flowing into the source/drain region SD, thereby providing an integrated circuit device with improved reliability.

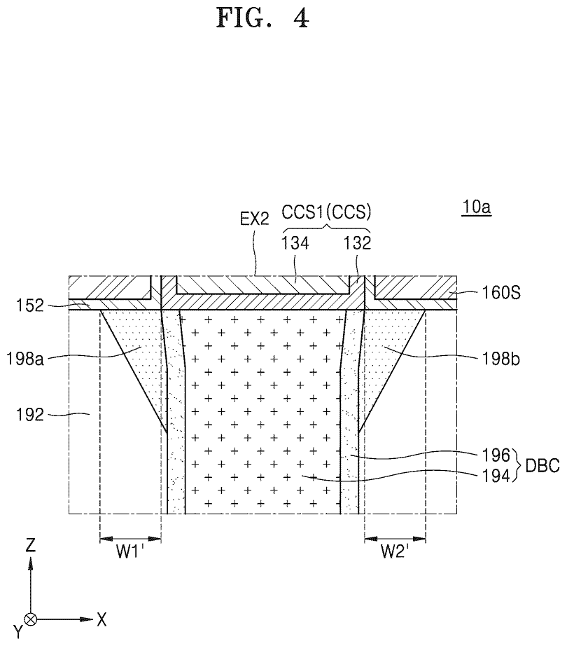

FIG. 4 is a diagram illustrating an integrated circuit device according to other embodiments of the technical idea of the present disclosure. FIG. 4 shows a portion corresponding to an area EX2 of FIG. 3A. In FIG. 4, the same reference numerals as in FIGS. 2 and 3A to 3C denote the same elements, and redundant descriptions thereof are omitted herein. Since the integrated circuit device 10a has only a slight difference in the shape of the back side contact DBC compared to the integrated circuit device 10 described with reference to FIGS. 2 and 3A to 3C, the difference is described.

Referring to FIG. 4, unlike in FIG. 3C, the back side contact DBC may be formed such that the cross-sectional area of the uppermost surface of the back side contact DBC is greater than the cross-sectional area of the lowermost surface of the back side contact DBC, resulting in a shape similar to the letter ‘Y’. This may occur during the manufacturing process of the integrated circuit device 10a, and the embodiments are not limited by the shape of the back side contact DBC.

In some cases, when the cross-sectional area of the uppermost surface of the back side contact DBC is formed to be greater than the cross-sectional area of the lowermost surface of the back side contact DBC, the back side contact DBC may not be in contact with the sub-gate part 160S.

In some cases, when the area of the uppermost surface of the back side contact DBC is greater than the area of the lowermost surface of the back side contact DBC, the widths W1′ and W2′ of the spacer structures 198a and 198b may be smaller than the widths W1 and W2 shown in FIG. 3C. The widths W1′ and W2′ are defined as the lengths in the first horizontal direction (X direction) on the uppermost surface of the back side contact DBC that is in contact with the gate dielectric layer 152. However, the widths W1′ and W2′ of the spacer structures 198a and 198b formed on both sides of the back side contact DBC can be adjusted based on the length of the sub-gate part 160S. The adjustment may be made within a range that prevents the spacer structures 198a and 198b from overlapping with other spacer structures formed on the upper sidewalls of neighboring back side contacts DBC.

Next, a method of manufacturing an integrated circuit device, according to embodiments of the technical idea of the present disclosure, is described.

FIGS. 5, 6, 7A, 7B, 8A, 8B, 9A, 9B, 10, 11A, 11B, 12, 13, 14, 15B, 15B, 16A, 16B, 17A, 17B, 18, 19, 20A, 20B, 21A, and 21B are diagrams illustrating, in a process sequence, a method of manufacturing an integrated circuit device, according to embodiments.

Specifically, FIGS. 5, 7A, 8A, 9A, 11A, 12, 13, 14, 15A, 16A, 17A, 18, 19, 20A, and 21A are diagrams showing a manufacturing process of a portion corresponding to the cross-section of X1-X1′ of FIG. 2, and FIGS. 6, 7B, 8B, 9B, 10, 11B, 15B, 16B, 17B, 20B, and 21B are diagrams showing a manufacturing process of a portion corresponding to the cross-section of Y1-Y1′ of FIG. 2.

In FIGS. 5, 6, 7A, 7B, 8A, 8B, 9A, 9B, 10, 11A, 11B, 12, 13, 14, 15B, 15B, 16A, 16B, 17A, 17B, 18, 19, 20A, 20B, 21A, and 21B, the same reference numerals as in FIGS. 2 and 3A to 3C denote the same members, and a detailed description thereof will be omitted herein.

Referring to FIG. 5, a plurality of sacrificial semiconductor layers 103 and a plurality of nanosheet semiconductor layers NS may be alternately stacked one-by-one on a substrate 102. The substrate 102 may include semiconductors, such as Si or Ge, or compound semiconductors, such as SiGe, SiC, GaAs, InAs, InGaAs, or InP. The terms “SiGe”, “SiC”, “GaAs”, “InAs”, “InGaAs”, and “InP” used herein refer to materials composed of the elements mentioned in each term and do not represent chemical formulae with a stoichiometric relationship. For example, the substrate 102 may be a bulk Si substrate. A stoichiometric relationship refers to the quantitative relationship between the reactants and products in a balanced chemical reaction. In a stoichiometric relationship, the relative amounts of each element or compound may be expressed as whole number ratios. For example, “SiOC” represents a material that contains silicon, oxygen, and carbon atoms, but the relative proportions of these elements may vary depending on the specific composition and synthesis method. According to embodiments of the present disclosure, the lack of a stoichiometric relationship indicates that the material does not necessarily have a fixed chemical formula, and the material's properties may depend on the specific atomic ratios present.

The plurality of sacrificial semiconductor layers 103 and the plurality of nanoshect semiconductor layers NS comprise semiconductor materials with different etch selectivity. In some embodiments, the plurality of nanosheet semiconductor layers NS are made of Si, while the plurality of sacrificial semiconductor layers 103 may include an SiGe layer. In some embodiments, the Ge content in the plurality of sacrificial semiconductor layers 103 may be constant throughout the layers. The specific Ge content in the SiGe layer of the sacrificial semiconductor layers 103 can be selected based on the desired etch selectivity.

As shown in FIG. 6, after forming a mask pattern MP1 on the structure from FIG. 5, the fin-type active region F1 is formed on the substrate 102. This is done by etching portions of the sacrificial semiconductor layers 103, the nanosheet semiconductor layers NS, and the substrate 102, using the mask pattern MP1 as an etching mask. The etching process defines a plurality of trench regions TI on the substrate 102, which are separated by the fin-type active region F1. In some embodiments, the mask pattern MP1 has a stacked structure including an oxide layer pattern and a silicon nitride layer pattern. The mask patterns MP1 extend parallel to each other in the first horizontal direction (X direction) on the substrate 102. After the etching process, a stack structure comprising the remaining portions of the sacrificial semiconductor layers 103 and the nanosheet semiconductor layers NS is present on the top surface of each fin-type active region F1.

Thereafter, a device isolation insulating layer P112 may be formed on the obtained resultant product. The device isolation insulating layer P112 may be formed with a thickness sufficient to fill the remaining spaces of the plurality of trench regions TI on an upper portion of an insulating stopper 106. The device isolation insulating layer P112 may include a silicon oxide layer.

Plasma enhanced chemical vapor deposition (PECVD), high density plasma CVD (HDP-CVD), inductively coupled plasma CVD (ICP-CVD), capacitor coupled plasma CVD (CCP), flowable chemical vapor deposition (FCVD), spin coating, and other methods may be used to form the device isolation insulating layer P112.

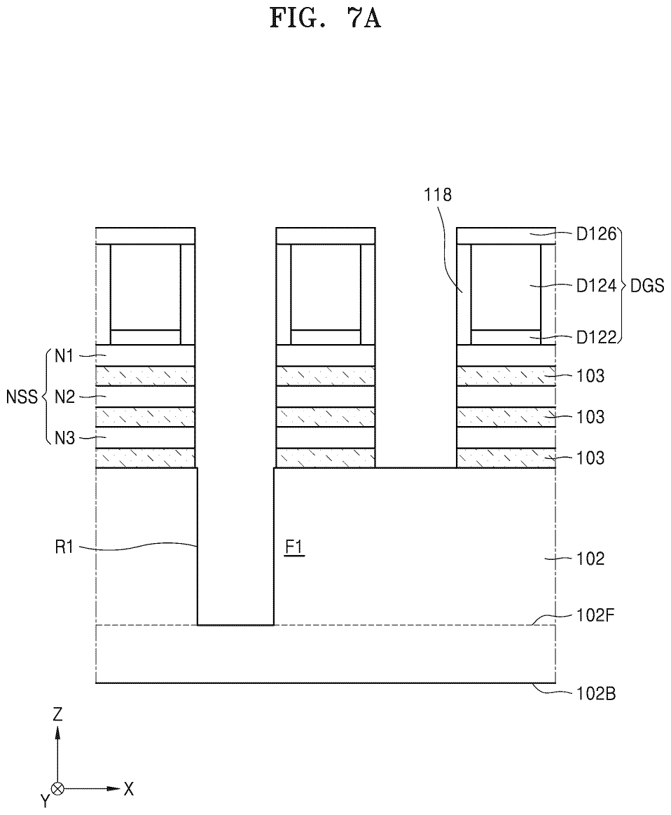

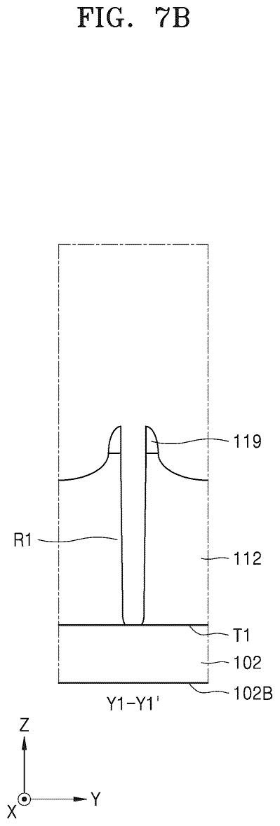

Referring to FIGS. 7A and 7B, a device isolation layer 112 may be formed by performing a recess process to remove the exposed mask pattern MP1 and a portion of the device isolation insulating layer P112 after planarizing the resultant product of FIG. 6 until the top surface of the mask pattern MP1 is exposed. As a result, the plurality of sacrificial semiconductor layers 103 and the plurality of nanosheet semiconductor layers NS (see FIG. 6) may protrude from the top surface of the device isolation layer 112.

To perform the recess process of the device isolation insulating layer P112, dry etching, wet etching, or a combination of dry and wet etching may be used. In this case, a wet etching process using NH₄OH, tetramethyl ammonium hydroxide (TMAH), potassium hydroxide (KOH), or other etchants, or a dry etching process such as inductively coupled plasma (ICP), transformer coupled plasma (TCP), electron cyclotron resistance (ECR), reactive ion etch (RIE), or similar methods may be used. When a recess process of the device isolation insulating layer P112 is performed using a dry etching process, a fluorine-containing gas such as CF4, a chlorine-containing gas such as Cl2, HBr, or similar gases may be used as an etching gas.

A plurality of dummy gate structures DGS may be formed on the stack structure of the plurality of sacrificial semiconductor layers 103 and the plurality of nanosheet semiconductor layers NS. Each of the plurality of dummy gate structures DGS may be formed to extend lengthwise in the second horizontal direction (Y direction). Each of the plurality of dummy gate structures DGS may have a structure in which an oxide layer D122, a dummy gate layer D124, and a capping layer D126 are sequentially stacked. In some embodiments, the oxide layer D122 may be a layer obtained by oxidizing the surfaces of each of the plurality of sacrificial semiconductor layers 103 and the plurality of nanosheet semiconductor layers NS. The dummy gate layer D124 may include polysilicon, and the capping layer D126 may include a silicon nitride layer.

After forming a plurality of outer insulating spacers 118 covering both sidewalls of each of the plurality of dummy gate structures DGS, portions of each of the plurality of sacrificial semiconductor layers 103 and the plurality of nanosheet semiconductor layers NS may be etched using the plurality of dummy gate structures DGSs and the plurality of outer insulating spacers 118 as etching masks. This process divides the plurality of nanosheet semiconductor layers NS into the plurality of nanosheet stacks NSS, each including the first nanosheet N1, the second nanosheet N2, and the third nanosheet N3. To partially etch each of the plurality of sacrificial semiconductor layers 103 and the plurality of nanosheet semiconductor layers NS, etching may be performed using dry etching, wet etching, or a combination of these methods.

Thereafter, a first recess R1 may be formed by etching a portion of the fin-type active region F1 that is exposed by etching a portion of each of the plurality of sacrificial semiconductor layers 103 and the plurality of nanosheet semiconductor layers NS. To form the first recess R1, etching may be performed using dry etching, wet etching, or a combination of these methods. After the first recess R1 is formed, the plurality of recess-side insulating spacers 119 arranged adjacent to the first recess R1 may be formed on the device isolation layer 112.

In some embodiments, an etching process for forming the first recess R1 may be performed until the bottom of the first recess R1 is at the same level as the top surface of the trench region TI defining the fin-type active region F1, in the vertical direction (Z direction). However, this is only an example, and the bottom of the first recess R1 may be at a level higher or lower than the level of the top surface of the trench region TI defining the fin-type active region F1.

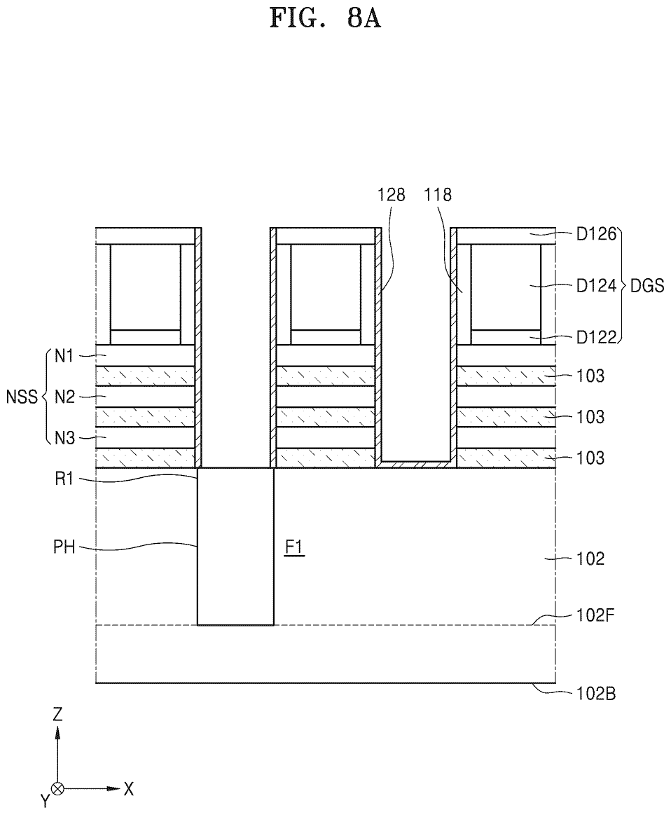

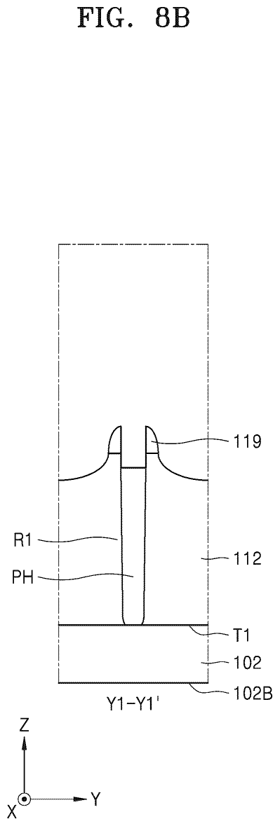

Referring to FIGS. 8A and 8B, a sacrificial insulating spacer 128 extending along a sidewall of the capping layer D126, a sidewall of the plurality of outer insulating spacers 118, and a sidewall of the plurality of nanosheet stacks NSS may be formed. The sacrificial insulating spacer 128 may extend to cover the top surface of the fin-type active region F1 exposed from the resultant product of FIGS. 7A and 7B.

For example, the sacrificial insulating spacer 128 may include a silicon nitride layer. The sacrificial insulating spacer 128 may be deposited through various methods such as PECVD, HDP CVD, ICP CVD, CCP CVD, FCVD, and spin coating processes.

Thereafter, a portion of the sacrificial insulating spacer 128 extending along the inner wall of the first recess R1 may be removed, and a place holder PH filling the first recess R1 may be formed. In some embodiments, the place holder PH may include an SiGe layer. For example, the place holder PH may include a monocrystalline SiGe layer, a polycrystalline SiGe layer, an amorphous SiGe layer, or a combination of these layers.

In some embodiments, the place holder PH may be deposited through various methods such as a PECVD process, an HDP CVD process, an ICP CVD process, a CCP CVD process, and an FCVD process using raw materials including an element precursor. In other embodiments, to form the place holder PH, an LPCVD process, an SEG process, or a CDE process may be performed using raw materials including an element semiconductor precursor. The element semiconductor precursor may include a Si source containing Si. Silane (SiH4), disilane (Si2H6), trisilane (Si3H8), dichlorosilane (SiH2Cl2), and similar materials may be used as the Si source, but the embodiments are not limited to these materials. In addition, the element semiconductor precursor may include a Ge source containing Ge. Germane (GeH4), digermane (Ge2H6), trigermane (Ge3H8), tetragermane (Ge4H10), dichlorogermane (Ge2H2Cl2), and similar materials may be used as the Ge source, but the embodiments are not limited to these materials. For example, the place holder PH may be formed by epitaxially growing the SiGe layer from the surface of the fin-type active region F1 exposed at the sidewall and bottom of the first recess R1. In this case, the place holder PH may include a monocrystalline SiGe layer.

In some embodiments, the Ge content in the place holder PH may be constant. The Ge content in the SiGe layer constituting the place holder PH may be selected within a range where the etch selectivity between the place holder PH and the fin-type active region F1 is different.

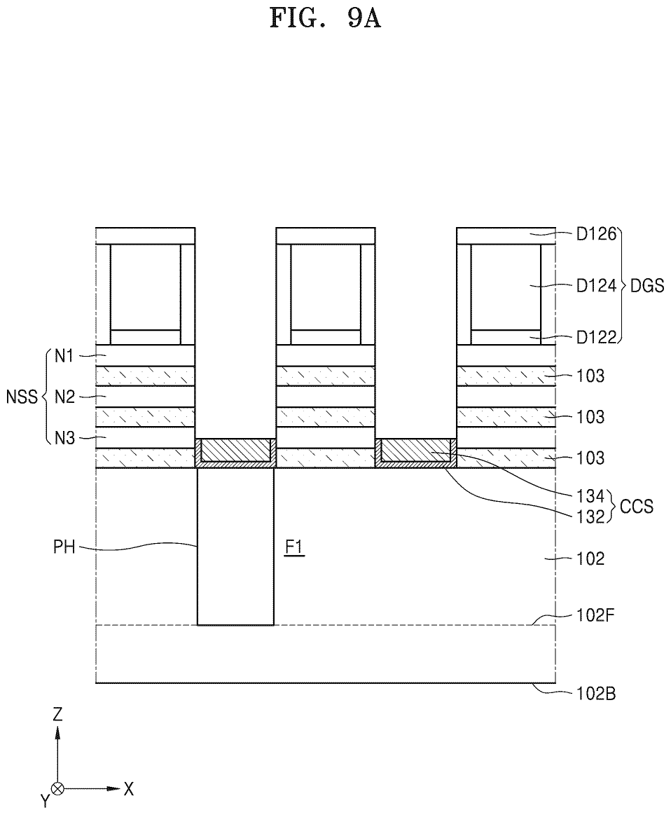

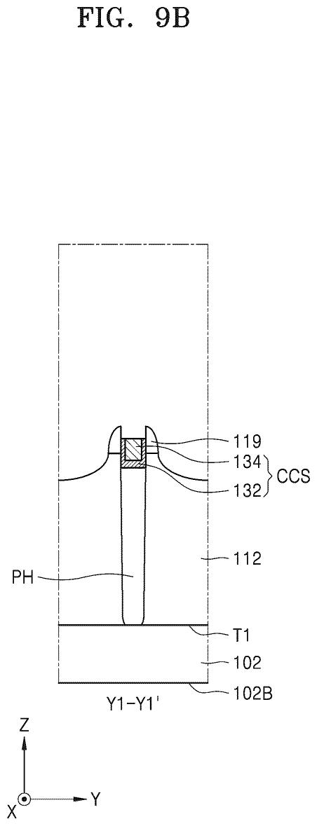

Referring to FIGS. 9A and 9B, the plurality of source/drain connection structures CCS may be formed after the sacrificial insulating spacer 128 is selectively removed. A liquid or gaseous etchant may be used to selectively remove the sacrificial insulating spacer 128. In some embodiments, to selectively remove the sacrificial semiconductor spacer 128, a CH3COOH-based etchant, such as an etchant including a mixture of CH3COOH, HNO3, and HF, or an etchant including a mixture of CH3COOH, H2O2, and HF, may be used, but the etchant is not limited to these examples.

Each of the plurality of source/drain connection structures CCS may include the first semiconductor layer 132 and the second semiconductor layer 134. The first semiconductor layer 132 and the second semiconductor layer 134 may include a monocrystalline, polycrystalline, or amorphous layer. The first semiconductor layer 132 and the second semiconductor layer 134 may include an Si layer or an SiGe layer. In some embodiments, the first semiconductor layer 132 may include an Si layer, and the second semiconductor layer 134 may include an SiGe layer.

The first semiconductor layer 132 and the second semiconductor layer 134 may be sequentially deposited through various methods such as a PECVD process, an HDP CVD process, an ICP CVD process, a CCP CVD process, and an FCVD process using raw materials including an element precursor. For example, the first semiconductor layer 132 may be formed by epitaxially growing an Si layer or an SiGe layer from the surface of the fin-type active region F1, the surface of the back side contact DBC, and the sidewall of the nanosheet stack NSS. The second semiconductor layer 134 may be formed by epitaxially growing an SiGe layer from the surface of the first semiconductor layer 132 and the sidewall of the nanosheet stack NSS.

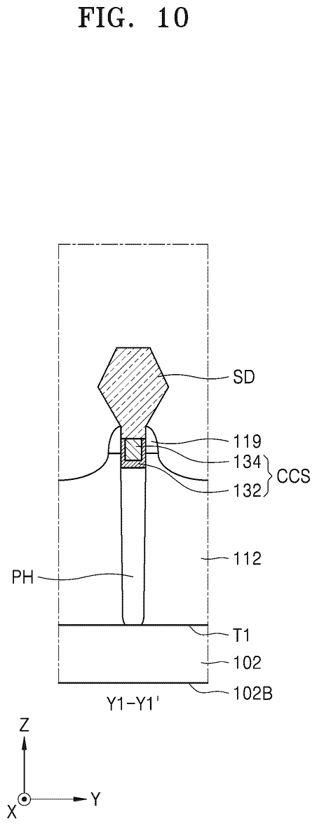

Referring to FIG. 10, the plurality of source/drain regions SD may be formed on the resultant product of FIGS. 9A and 9B.

To form the plurality of source/drain regions SD, a semiconductor material may be epitaxially grown from the surface of the source/drain connection structure CCS exposed on the resultant product of FIGS. 9A and 9B and the sidewall of each of the first nanosheet N1, the second nanosheet N2, and the third nanosheet N3 included in the nanosheet stack NSS.

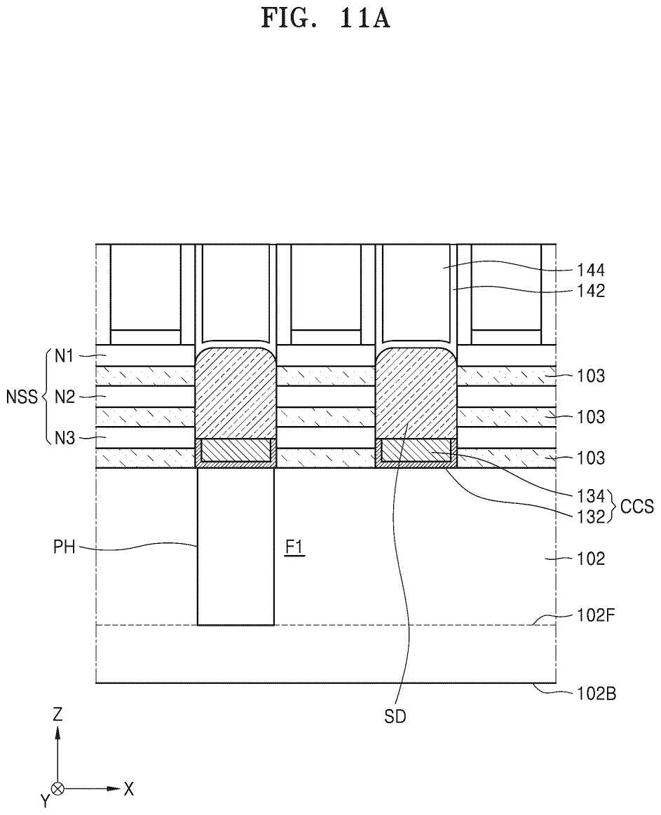

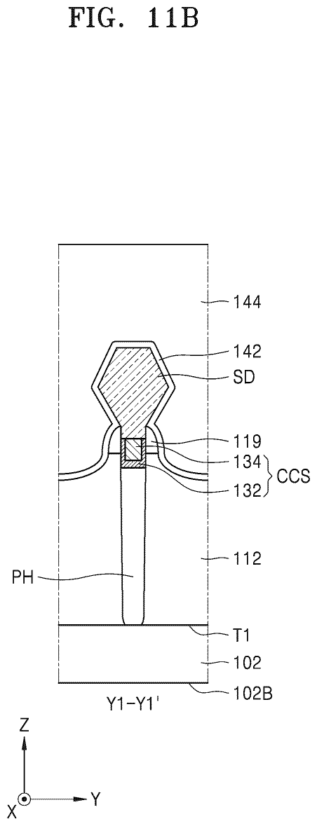

Referring to FIGS. 11A and 11B, the insulating liner 142 covering the resultant product of FIG. 10 is formed, and the inter-gate insulating layer 144 is formed on the insulating liner 142. Then, a portion of each of the insulating liner 142 and the inter-gate insulating layer 144 is etched to expose the top surfaces of the plurality of capping layers D126. Thereafter, the dummy gate layer D124 may be exposed by removing the plurality of capping layers D126, and the insulating liner 142 and the inter-gate insulating layer 144 may be partially removed so that the top surface of the inter-gate insulating layer 144 and the top surface of the dummy gate layer D124 are at approximately the same level.

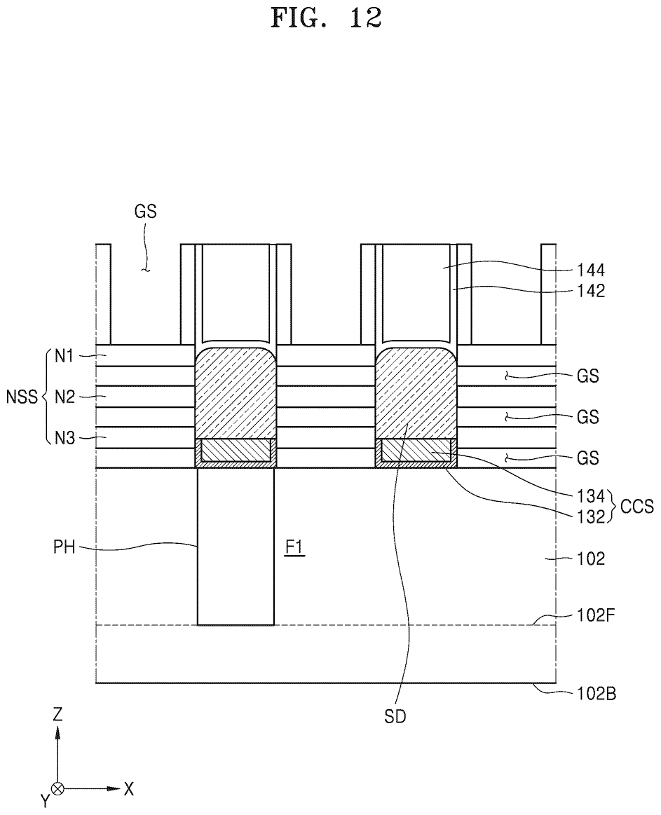

Referring to FIG. 12, a gate space GS may be provided by removing the dummy gate layer D124 and the lower oxide layer D122 from the resultant product of FIGS. 11A and 11B, and the plurality of nanosheet stacks NSS may be exposed through the gate space GS. Thereafter, the plurality of sacrificial semiconductor layers 103 may be removed through the gate space GS to extend the gate space GS to spaces between the first nanosheet N1 and the second nanosheet N2, between the second nanosheet N2 and the third nanosheet N3, and between the first nanosheet N1 and the top surface of the fin-type active region F1. In some embodiments, differences in etching selectivity among the first nanosheet N1, the second nanosheet N2, the third nanosheet N3, and the plurality of sacrificial semiconductor layers 103 may be used to selectively remove the plurality of sacrificial semiconductor layers 103.

To selectively remove the plurality of sacrificial semiconductor layers 103, a liquid or gaseous etchant may be used. In some embodiments, to selectively remove the plurality of sacrificial semiconductor layers 103, a CH3COOH-based etchant, such as an etchant including a mixture of CH3COOH, HNO3, and HF, or an etchant including a mixture of CH3COOH, H2O2, and HF, may be used, but the etchant is not limited to these examples.

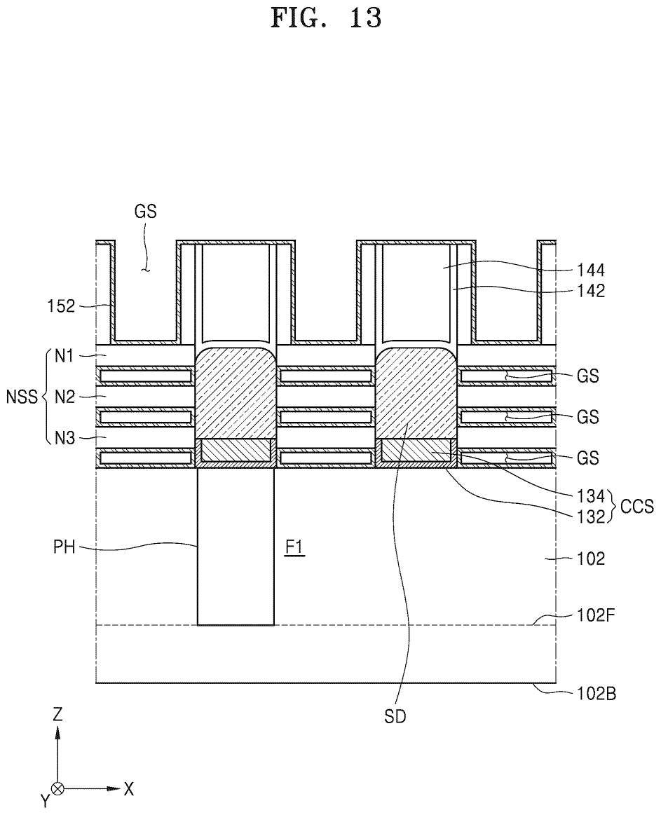

Referring to FIG. 13, from the resultant product of FIG. 12, the gate dielectric layer 152 covering the exposed surface of each of the first nanosheet N1, the second nanosheet N2, the third nanosheet N3, and the fin-type active region F1 may be formed. An atomic layer deposition (ALD) process may be used to form the gate dielectric layer 152.

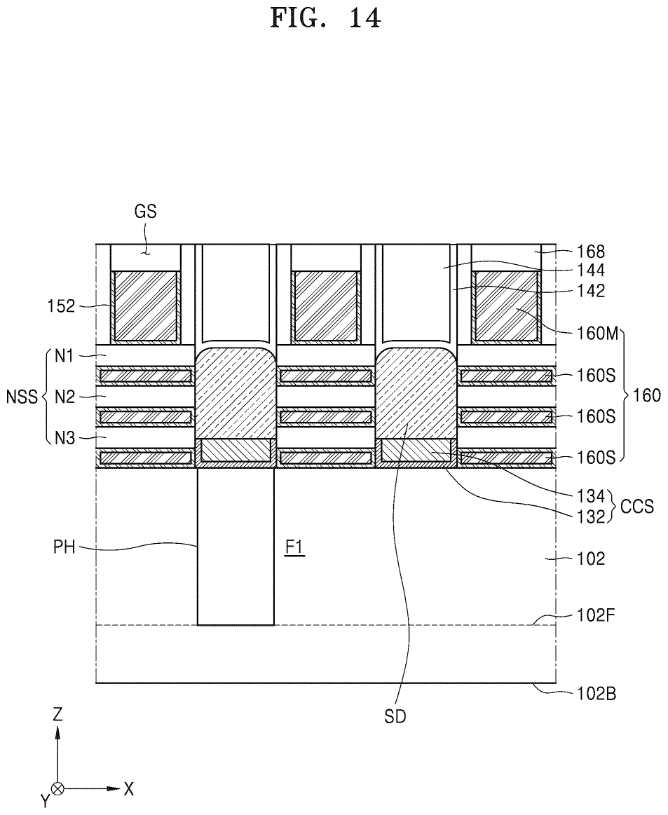

Referring to FIG. 14, the gate line 160 is formed, covering the top surface of the inter-gate insulating layer 144 and filling the gate space GS (see FIG. 13) on the gate dielectric layer 152. Additionally, the capping insulating pattern 168 is formed, covering the top surface of both the gate line 160 and the gate dielectric layer 152 in the gate space GS.

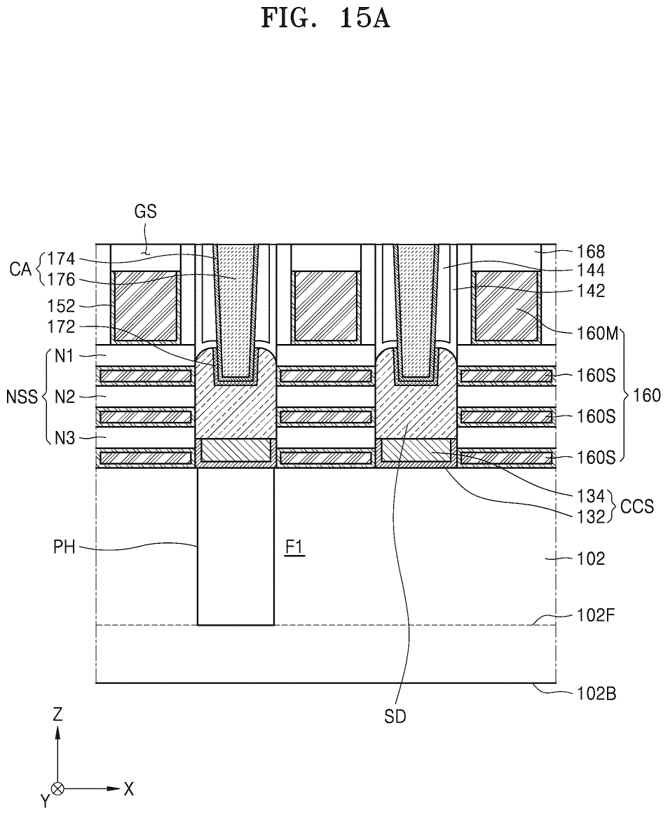

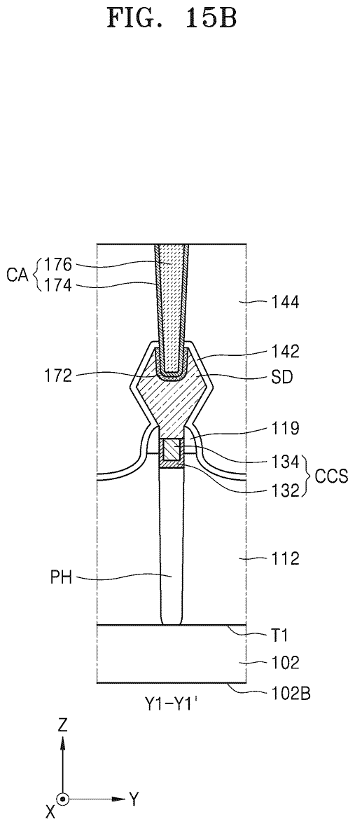

Referring to FIGS. 15A and 15B, a source/drain contact hole (not shown) exposing the source/drain region SD is formed by extending through the insulating structure, which includes the insulating liner 142 and the inter-gate insulating layer 144, from the structure of FIG. 14. Next, a partial region of the source/drain region SD is removed by an anisotropic etching process through the source/drain contact hole, causing the source/drain contact hole to extend in the vertical direction (Z direction). Following this, the metal silicide layer 172 is formed on the source/drain region SD exposed at the bottom of the source/drain contact hole. In some embodiments, to form the metal silicide layer 172, a process is included that involves forming a metal liner (not shown) that conformally covers an exposed surface of the source/drain region SD and inducing a reaction between the source/drain region SD and the metal constituting the metal liner through heat treatment. Once the metal silicide layer 172 is formed, the remaining portion of the metal liner is removed. During the formation of the metal silicide layer 172, a portion of the source/drain region SD may be consumed. In some embodiments, when the metal silicide layer 172 includes a titanium silicide layer, the metal liner may include a Ti layer.

Subsequently, the source/drain contact CA, which includes the conductive barrier pattern 174 and the contact plug 176, is formed on the metal silicide layer 172.

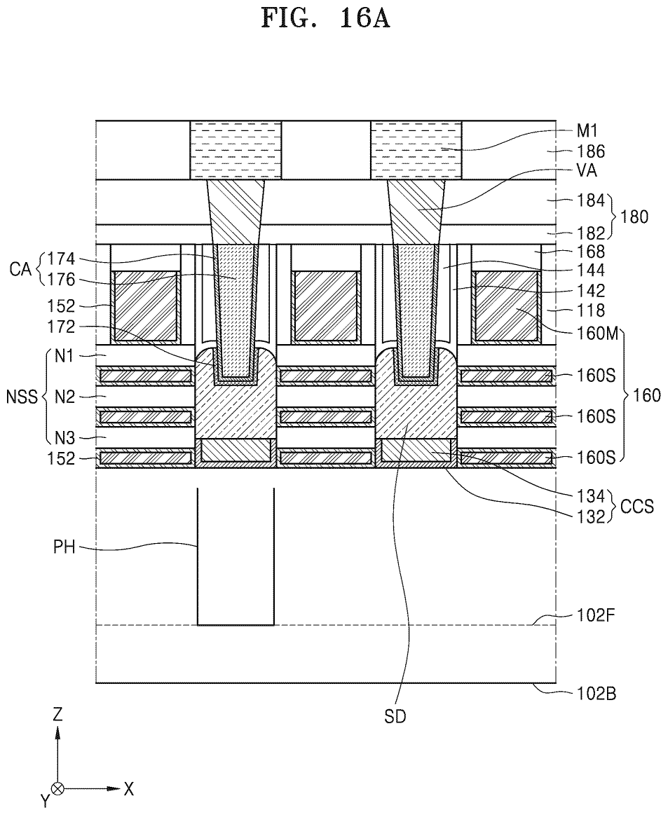

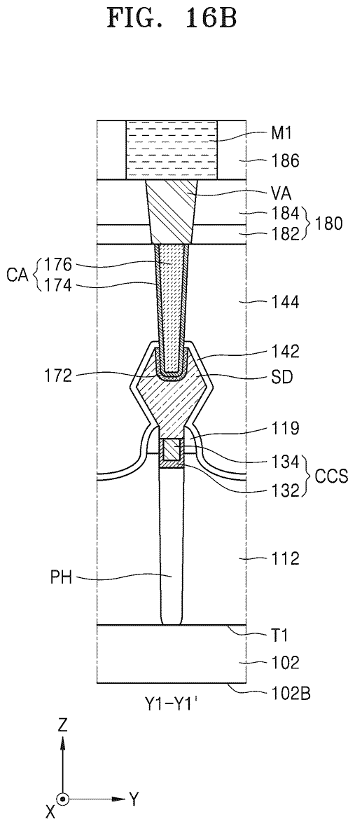

Referring to FIGS. 16A and 16B, starting from the structure of FIGS. 15A and 15B, an etch stop layer 182 and an interlayer insulating layer 184 are sequentially formed, covering a top surface of the inter-gate insulating layer 144, the plurality of source/drain contacts CA, and the plurality of capping insulating patterns 168, creating the upper insulating structure 180. Subsequently, the plurality of source/drain via contacts VA, which are connected to the plurality of source/drain contacts CA, are formed by extending through the upper insulating structure 180 in the vertical direction (Z direction).

After that, the upper insulating layer 186, covering the upper insulating structure 180, and the upper wiring layer M1, extending through the upper insulating layer 186 and connected to the source/drain via contact VA may be formed.

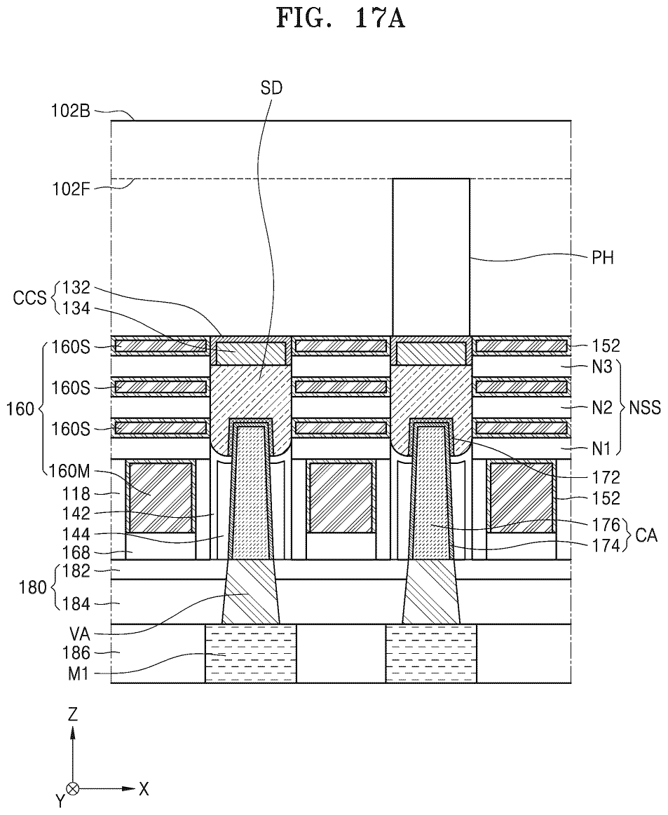

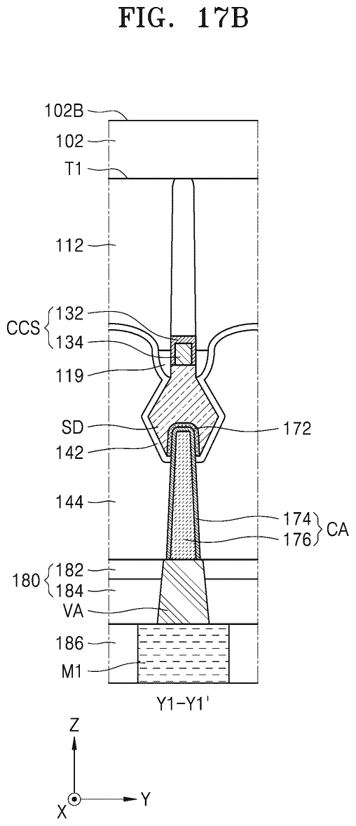

Referring to FIGS. 17A and 17B, the resultant product of FIGS. 16A and 16B may be arranged such that a rear surface 102B of the substrate 102 faces upward and a front surface 102F of the substrate 102 faces downward. Thereafter, a chemical mechanical polishing process may be performed on the rear surface 102B of the substrate 102 to expose the place holder PH.

Referring to FIG. 18, the fin-type active region F1 surrounding the place holder PH of FIGS. 17A and 17B may be selectively removed. To selectively remove the fin-type active region F1 surrounding the place holder PH, the difference in etch selectivity among the fin-type active region F1, the place holder PH, and the gate dielectric layer 152 may be used. For example, a wet etching process may be performed to selectively remove the fin-type active region F1 surrounding the exposed place holder PH.

In this case, a portion of the fin-type active region F1 may remain after the selective removal process of the fin-type active region F1, forming the spacer structure 198. For example, when performing an etching process using KOH, NHOH4, or TMAH, the spacer structure 198 may have an angular shape because the etching speed of the crystal surface in a specific direction (e.g., the crystal surface in the (111) direction) is different than that in other directions. For these reasons, the spacer structure 198 may remain by being formed in a triangular shape surrounding the place holder PH. The spacer structure 198 may be formed in a symmetrical shape on both sidewalls of the place holder PH. A sidewall of the spacer structure 198 may be in contact with the place holder PH, and a bottom surface thereof may be in contact with the gate dielectric layer 152.

Referring to FIG. 19, the gap-fill insulating layer 192 may be formed in a space created by selectively removing the fin-type active region F1 (FIGS. 17A, 17B, and 18) surrounding the exposed place holder PH from the resultant product of FIG. 18. To form the gap-fill insulating layer 192, various methods such as PVD, CVD, or ALD processes may be used.

Thereafter, a chemical mechanical polishing process may be performed on the top surface of the gap-fill insulating layer 192 to flatten the top surface of the gap fill insulating layer 192.

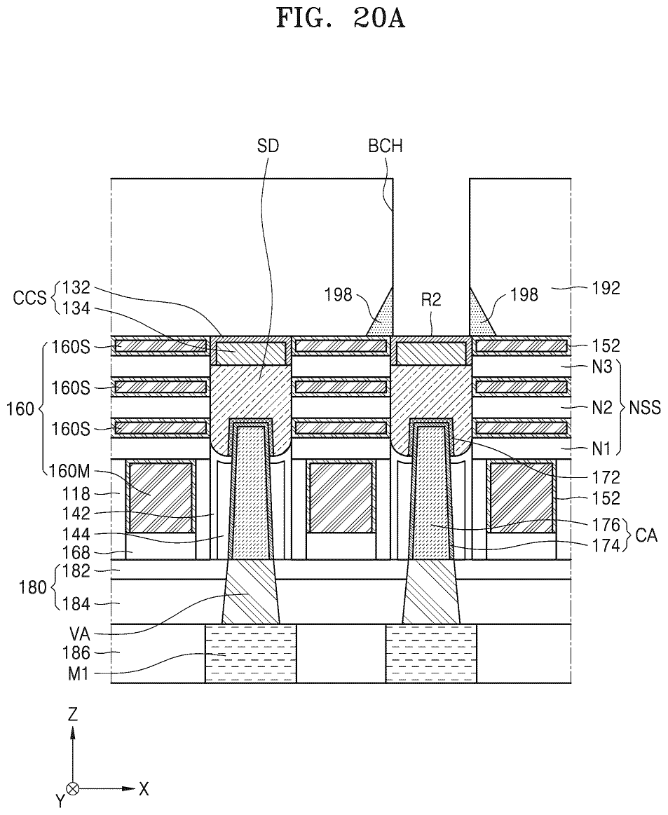

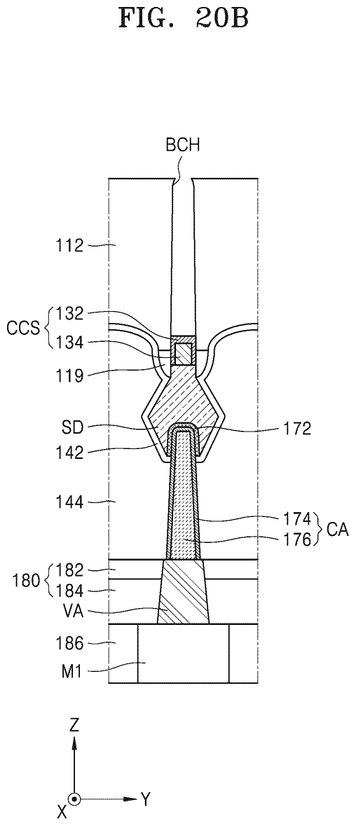

Referring to FIGS. 20A and 20B, an etching process for removing the place holder PH may be carried out to form the back side contact hole BCH in the resultant product of FIG. 19. The etching process for removing the place holder PH may be a selective etching process using the place holder PH, which includes a material different from that of the gap-fill insulating layer 192. For example, the RIE may be performed to remove the place holder PH. The sidewall of the spacer structure 198 may be exposed by the removal of the place holder PH.

The second recess R2 may be formed at the position where the place holder PH is removed, and the source/drain connection structure CCS may be exposed through the bottom surface of the second recess R2.

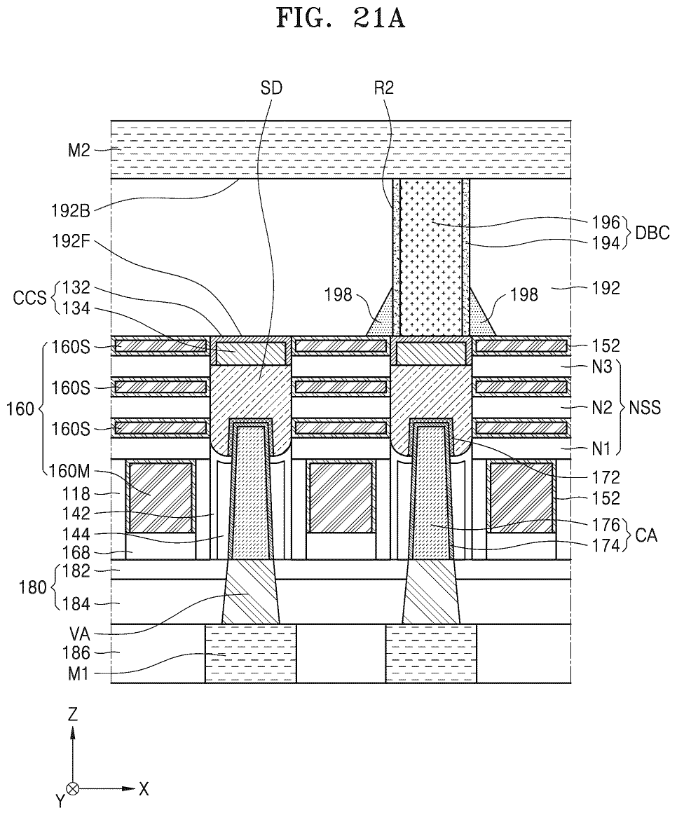

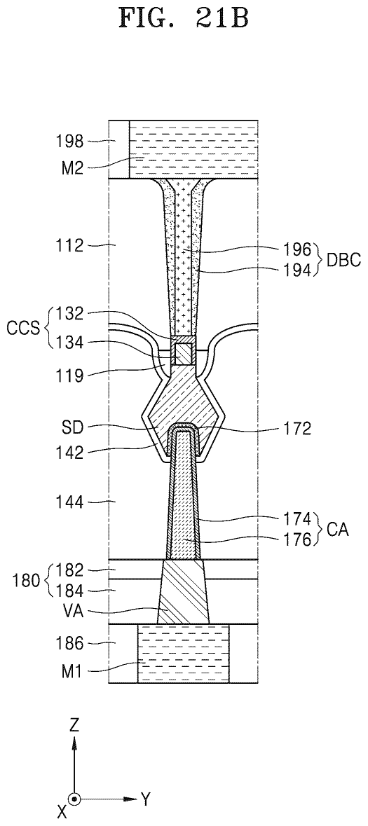

Referring to FIGS. 21A and 21B, the back side contact DBC may be formed inside the second recess R2. The back side contact DBC may include the back side barrier layer 194 and the back side via 196. After the back side barrier layer 194 is formed to conformally extend along the inner wall of the second recess R2, the back side via 196 may be sequentially formed on the back side barrier layer 194. The back side barrier layer 194 and the back side via 196 may be deposited using CVD or ALD and may be deposited using various processes.

Thereafter, the lower insulating layer 199 covering the back side contact DBC, the gap fill insulating layer 192, and the plurality of device isolation layers 112, and the lower wiring layer M2 extending through the lower insulating layer 199 and connected to the back side contact DBC may be formed.

While the present disclosure has been particularly shown and described with reference to embodiments thereof, it will be understood that various changes in form and details may be made therein without departing from the spirit and scope of the following claims.

What is claimed is:

1. An integrated circuit device comprising:
a plurality of device isolation layers extending in a first horizontal direction and spaced apart from each other in a second horizontal direction perpendicular to the first horizontal direction;
a gap-fill insulating layer disposed between the plurality of device isolation layers;
a plurality of gate lines disposed on the gap-fill insulating layer and extending lengthwise in the second horizontal direction;
a plurality of source/drain regions disposed between adjacent gate lines of the plurality of gate lines;
a plurality of source/drain connection structures disposed under the plurality of source/drain regions, the plurality of source/drain connection structures including a first source/drain connection structure and a second source/drain connection structure;
a back side contact extending through the gap-fill insulating layer in a third direction perpendicular to the first and second horizontal directions and connected to the first source/drain connection structure; and
first and second spacer structures in contact with upper sidewalls of the back side contact,
wherein the first and second spacer structures are disposed between the gap-fill insulating layer and the first source/drain connection structure.

2. The integrated circuit device of claim 1, wherein the first and second spacer structures comprise Si.

3. The integrated circuit device of claim 1, wherein the first and second spacer structures have a triangular shape having a sidewall facing a sidewall of the back side contact.

4. The integrated circuit device of claim 1, wherein the first and second spacer structures have mirror symmetrical shapes with respect to the back side contact.

5. The integrated circuit device of claim 1, wherein the first and second spacer structures comprise a crystal plane with a Miller-index (111).

6. The integrated circuit device of claim 1, further comprising:
a gate dielectric layer disposed between the source/drain regions and the plurality of gate lines,
wherein the first and second spacer structures are disposed between the gate dielectric layer and the back side contact, and
the back side contact is spaced apart from the gate dielectric layer by the first and second spacer structures.

7. The integrated circuit device of claim 1, wherein:
the back side contact covers a first portion of a bottom surface of the first source/drain connection structure, and
the first and second spacer structures cover a second portion of the bottom surface of the first source/drain connection structure, wherein the second portion is a remaining portion of the bottom surface not covered by the back side contact.

8. The integrated circuit device of claim 1, wherein each of the plurality of source/drain connection structures comprises:
a first semiconductor layer; and
a second semiconductor layer having a sidewall and a bottom surface, wherein the first semiconductor layer surrounds the sidewall and the bottom surface of the second semiconductor layer.

9. The integrated circuit device of claim 1, wherein:
the gap-fill insulating layer comprises a silicon oxide layer, and
the gap-fill insulating layer surrounds sidewalls of the first and second spacer structures.

10. The integrated circuit device of claim 1, wherein an uppermost surface of each of the first and second spacer structures has a length not exceeding about 2 nm in the first horizontal direction.

11. The integrated circuit device of claim 1, wherein, in a plan view, the back side contact is surrounded by a region occupied by the first source/drain connection structure.

12. An integrated circuit device comprising:
a back side contact;
first and second spacer structures surrounding a first portion of the back side contact in a first horizontal direction and having a mirror symmetrical shape with respect to the back side contact;
a gap-fill insulating layer surrounding a second portion of the back side contact in the first horizontal direction, the second portion being below the first portion surrounded by the first and second spacer structures;
a source/drain connection structure disposed above and in contact with the back side contact;
a source/drain region electrically connected to the back side contact through the source/drain connection structure;
a plurality of gate lines spaced apart from the source/drain region; and
a gate dielectric layer disposed between the source/drain region and the plurality of gate lines,
wherein the first and second spacer structures separate the back side contact from the gate dielectric layer, and
the back side contact has a first horizontal width at an upper portion that is greater than a second horizontal width at a lower portion.

13. The integrated circuit device of claim 12, wherein each of the first and second spacer structures comprises:
a first surface in contact with a sidewall of the back side contact;
a second surface in contact with the gate dielectric layer; and
a third surface having a Miller-index (111).

14. The integrated circuit device of claim 12, wherein the source/drain connection structure comprises:
a first semiconductor layer; and
a second semiconductor layer having a sidewall and a bottom surface, wherein the first semiconductor layer surrounds the sidewall and the bottom surface of the second semiconductor layer,
wherein a top surface of the back side contact covers a first portion of a bottom surface of the source/drain connection structure, and
top surfaces of the first and second spacer structures cover a second portion of the bottom surface of the source/drain connection structure, the second portion being a remaining portion of the bottom surface not covered by the back side contact.

15. The integrated circuit device of claim 12, wherein the first and second spacer structures have a first horizontal width at upper portions that is greater than a second horizontal width at lower portions.

16. The integrated circuit device of claim 12, wherein the first and second spacer structures comprise silicon.

17. An integrated circuit device comprising:
a plurality of device isolation layers extending lengthwise in a first horizontal direction and spaced apart from each other in a second horizontal direction perpendicular to the first horizontal direction;
a gap-fill insulating layer disposed between two adjacent device isolation layers of the plurality of device isolation layers;
at least one nanosheet disposed on the gap-fill insulating layer, spaced apart from a top surface of the gap-fill insulating layer in a vertical direction, and facing the top surface of the gap-fill insulating layer;
a gate line surrounding the at least one nanosheet on the gap-fill insulating layer and extending lengthwise in the second horizontal direction;
a gate dielectric layer surrounding the gate line and separating the at least one nanosheet from the gate line;
a source/drain region adjacent to the gate line on the gap-fill insulating layer and in contact with the at least one nanosheet;
a source/drain connection structure in contact with a bottom surface of the source/drain region and including a first semiconductor layer and a second semiconductor layer;
a back side contact extending from a bottom surface of the gap-fill insulating layer in the vertical direction and covering a first portion of a bottom surface of the source/drain connection structure; and
a first spacer structure and a second spacer structure,
wherein each of the first and second spacer structures has a triangular shape in a cross-sectional view and includes:
a first surface disposed between the back side contact and the gap-fill insulating layer and covering a second portion of the bottom surface of the source/drain connection structure, the second portion being a remaining portion of the bottom surface not covered by the back side contact; and
a second surface in contact with a sidewall of the back side contact.

18. The integrated circuit device of claim 17, wherein the first and second spacer structures comprise a crystal plane with a Miller-index (111).

19. The integrated circuit device of claim 17, wherein the first and second spacer structures have mirror symmetrical shapes with respect to the back side contact.

20. The integrated circuit device of claim 17, wherein the first and second spacer structures comprise Si.
